(19) United States
(12) Patent Application Publication
(10) Pub. No.: US 2026/0139359 A1
(43) Pub. Date: May 21, 2026

(54) SYNTHESIS METHOD FOR SULFUR-POROUS CARBON COMPOSITES WITH TUNABLE CRYSTALLINITY AND MORPHOLOGY FOR LITHIUM/SULFUR BATTERIES

(71) Applicants: Yoon HWA, Chandler, AZ (US); David W. WRIGHT, Mesa, AZ (US); Yuhui AN, Scottsdale, AZ (US)

(72) Inventors: Yoon HWA, Chandler, AZ (US); David W. WRIGHT, Mesa, AZ (US); Yuhui AN, Scottsdale, AZ (US)

(73) Assignee: Arizona Board of Regents on Behalf of Arizona State University, Scottsdale, AZ (US)

(21) Appl. No.: 19/388,851

(22) Filed: Nov. 13, 2025

Related U.S. Application Data
(60) Provisional application No. 63/723,029, filed on Nov. 20, 2024.

(51) Int. Cl. C23C 14/22; C23C 14/06; C23C 14/24; H01M 4/36; H01M 4/58; H01M 4/587

(52) U.S. Cl. CPC C23C 14/223; C23C 14/0623; C23C 14/243; H01M 4/366; H01M 4/5815; H01M 4/587

(57) ABSTRACT

A system and method of making a sulfur-carbon composite are disclosed. A nanoporous carbon powder is placed in a container and a sulfur source is stored in a staging tube gaseously coupled to the container, allowing delivery of the sulfur source into the container without introducing any gases. The carbon is desorbed by cyclically heating, evacuating, and backfilling with an inert gas until a predetermined desorption temperature is reached, thereby forming a desorbed carbon powder. After cooling, the sulfur source is transferred onto the desorbed powder, the container is evacuated and sealed, and a thermal gradient is applied. Excess sulfur may be condensed away from the composite. A system includes a container having a carbon powder and a staging tube coupled to the container through an O-ring union tee vacuum fitting. A sulfur-carbon composite includes nano-scale porous carbon having nanometer-scale sulfur dispersed in the pores and on a surface.

### RELATED APPLICATIONS

This application claims the benefit of U.S. provisional patent application 63/723,029, filed Nov. 20, 2024, to Yoon Hwa et al., titled “SYNTHESIS METHOD FOR SULFUR-POROUS CARBON COMPOSITES WITH TUNABLE CRYSTALLINITY AND MORPHOLOGY FOR LITHIUM/SULFUR BATTERIES,” the entirety of the disclosure of which is hereby incorporated by this reference.

### TECHNICAL FIELD

Aspects of this document relate generally to the fabrication of battery electrodes, and more specifically relate to the fabrication of battery cathodes.

### BACKGROUND

As the transportation industry shifts towards electric vehicles in an effort to reduce environmental impact, sustainable battery manufacturing will become critical for the development of a clean-energy economy in the US. Batteries will need improved performance while being less expensive and more environmentally sound to manufacture. The current state-of-the-art method for battery electrode manufacturing will be unable to meet the needs of the future on a number of fronts, including environmental impact, advancing electrode structure, and reduced manufacturing costs.

Batteries based on lithium-ion (Li-ion) technology typically utilize cobalt and nickel as part of the cathode. However, concentrated sources of cobalt and nickel used in Li-ion batteries are limited in supply and concentrated in specific geographic regions. The sourcing of cobalt and nickel is also associated with significant environmental and ethical concerns.

Lithium/sulfur (Li/S) batteries offer exceptionally high theoretical specific capacity and theoretical specific energy, higher than that of traditional Li-ion batteries. However, the low electrical conductivity of sulfur and the dissolution of intermediate lithium polysulfides (Li—PS) lead to lower energy density and reduced cycle life. The “Li—PS shuttle effect” occurs when Li—PS dissolves from the cathode into the electrolyte and migrates to the anode, where they are reduced and re-oxidized. This parasitic transport depletes active sulfur from the cathode and increases internal resistance, causing capacity fading and a reduced cycle life in Li/S batteries. In addition, the intrinsic low conductivity of sulfur severely limits its electrochemical performance, necessitating the use of conductive additives that can reduce the overall energy density.

In addition, sulfur undergoes significant volumetric change during lithiation and delithiation, leading to mechanical stress and degradation of the sulfur cathode structure, and thus to capacity decay in Li/X batteries. These limitations have hindered the practical application and widespread adoption of Li/S batteries within the emerging clean-energy economy.

### SUMMARY

According to some embodiments, a method of making a sulfur-carbon composite comprises providing an amorphous carbon powder comprising nanometer-sized pores disposed in a container, gaseously coupling a staging tube containing a sulfur source to the amorphous carbon powder, evacuating the container and the staging tube to remove ambient air and surface-adsorbed gaseous species, backfilling the container to about ⅔ atmosphere absolute (ATA) with a high purity inert gas, desorbing the amorphous carbon powder by heating the container proximal to the amorphous carbon powder, evacuating the container to about ⅓ ATA to at least partially remove gaseous species and moisture, backfilling the container to about ⅔ ATA with the high purity inert gas, and repeating heating, evacuating, and backfilling until a predetermined desorption temperature is reached, cooling the container to room temperature under the high purity inert gas, transferring the sulfur source from the staging tube onto the desorbed amorphous carbon powder in the container, evacuating the container to a vacuum and sealing the desorbed amorphous carbon powder and the sulfur source in the container, applying a temperature gradient across the container, with a high temperature zone adjacent the desorbed amorphous carbon powder and the sulfur source at a sulfur infiltration temperature, and a low temperature zone distal to the desorbed amorphous carbon powder and the sulfur source, maintaining the temperature gradient for a duration sufficient to vaporize and infiltrate sulfur into the desorbed amorphous carbon powder to form a composite, and cooling the container to condense excess sulfur away from the composite.

Particular embodiments may comprise one or more of the following features. The method may further comprise maintaining the temperature gradient during cooling, wherein the temperature gradient causes the excess sulfur to condense in the low temperature zone distal to the composite. The desorption temperature may be substantially equal to or greater than the sulfur infiltration temperature. The sulfur infiltration temperature may be within a range of from about 400° C. to about 800° C. The container may be filled with the amorphous carbon powder to between about 30% and 60% of its volume. The vacuum may be about 9×10⁻⁵ torr. The method may further comprise hermetically sealing the container. Transferring the sulfur source from the staging tube onto the desorbed amorphous carbon powder may be performed under high purity inert gas.

According to some embodiments, a system for nano-scale dispersion of sulfur into a porous carbon electrode comprises a container having carbon powder disposed therein, the carbon powder comprising nanometer-sized pores, a staging tube having sulfur disposed therein, the staging tube coupled to the container with an O-ring union tee vacuum fitting, the staging tube configured to transfer the sulfur onto the carbon powder disposed in the container, a vacuum pump coupled to the container and the staging tube via the O-ring union tee vacuum fitting, a gas supply coupled to the container and the staging tube via the O-ring union tee vacuum fitting, and a heating source configured to receive the container, wherein the staging tube is disposed away from the heating source when the container is disposed in the heating source.

Particular embodiments may comprise one or more of the following features. The container may be configured for sealing below the O-ring union tee vacuum fitting. The container may be configured for sealing under high vacuum. The container may be configured for hermetic sealing. The heating source may be configured to apply a temperature gradient across the container to facilitate sulfur infiltration and condensation control.

According to some embodiments, a sulfur-carbon composite comprises porous carbon substantially free of moisture and adsorbed gaseous species and having nanometer-scale pores disposed therein, and nanometer-scale sulfur dispersed in the nanometer-scale pores and on a surface of the porous carbon, wherein the sulfur has a nanometer-scale particle size.

Particular embodiments may comprise one or more of the following features. The sulfur may comprise non-crystalline and/or nanocrystalline sulfur. The sulfur may be immobilized within the nanometer-scale pores of the sulfur-carbon composite. The porous carbon may comprise an interconnected, electrically conductive network. The sulfur-carbon composite may be free of sulfur agglomerates and aggregates. The sulfur may be chemically bonded with the porous carbon. The sulfur may be distributed uniformly within the porous carbon.

The foregoing and other aspects, features, and advantages will be apparent from the description and drawings, and from the claims.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Implementations will hereinafter be described in conjunction with the appended and/or included drawings.

FIG. 1 illustrates a system for a carbon desorption process according to some embodiments.

FIG. 2 illustrates a sealed container after a carbon desorption process according to some embodiments.

FIG. 3 illustrates a sealed container disposed in a furnace as part of a sulfur infiltration process according to some embodiments.

FIGS. 4A-4I are transmission electron microscopy (TEM) and scanning electron microscopy (SEM) images illustrating the effect of different infiltration methods and temperatures on sulfur distribution within the highly porous carbon powder according to some embodiments. FIGS. 4A-4C are related to the conventional melt diffusion method, FIGS. 4D-4F are related to the presently disclosed method at 200° C., and FIGS. 4G-4I are related to the presently disclosed method at 600° C.

FIG. 5 depicts x-ray diffraction (XRD) analysis results showing the crystallinity of sulfur in different fabricated sulfur-carbon (S/C) composites according to some embodiments, where crystalline α-S peaks are evident in melt-diffused and 200° C. vapor-assisted samples but absent in the 400° C. sample and the 600° C. sample.

FIG. 6 shows thermogravimetric analysis (TGA) results for various S/C composites according to some embodiments.

FIG. 7 shows X-ray photoelectron spectroscopy (XPS) results for various S/C composites according to some embodiments.

FIGS. 8A-8C illustrate galvanostatic charge and discharge performance of a melt diffusion cathode (FIG. 8A) and 200° C. (FIG. 8B) and 600° C. (FIG. 8C) S/C composite cathodes in a coin-type Li/S battery according to some embodiments.

FIG. 9 shows a rate capability test of Li/S batteries according to some embodiments.

FIG. 10 illustrates a Li/S battery according to some embodiments.

FIG. 11 is a schematic illustration of a S/C composite synthesis method according to some embodiments. High-vacuum preheating removes volatiles from Ketjenblack pores and then sulfur is infiltrated under sealed conditions as 200-600° C. via vapor and melt transport.

FIGS. 12A-12L illustrate a structural and morphological comparison of S/C composites prepared via different sulfur infiltration methods according to some embodiments. SEM image and high-angle annular dark-field scanning transmission electron microscopy (HAADF-TEM) images with corresponding electron energy loss spectroscopy (EELS) carbon and sulfur maps highlighting surface-localized S/C composites synthesized via melt-diffusion method (FIGS. 12A-12D), vapor-assisted infiltration at 200° C. (FIGS. 12E-12H), and vapor-assisted infiltration at 600° C. (FIGS. 12I-12L), showing progressive suppression of particle aggregation.

FIGS. 13A-13E illustrate a structural characterization of S/C composites via pore analysis and scattering techniques according to some embodiments. FIG. 13A illustrates the surface area analysis of various S/C composites according to some embodiments. FIG. 13B illustrates the Barrett-Joyner-Halenda (BJH) pore size distribution results of various S/C composites according to some embodiments. FIGS. 13C and 13D illustrate the small angle X-ray scattering (SAXS) intensity profiles and corresponding fits to the modified Porod law (q⁴I vs. q²) of S/C composites, showing nanoconfined sulfur dispersion. FIG. 13E illustrates 2D wide angle x-ray scattering (WAXS) patterns comparing crystalline α-S formation in conventionally melt-diffused composites and amorphous dispersion in vapor-infiltrated samples.

FIGS. 14A-14F illustrate a structural and chemical characterization of sulfur species in S/C composites according to some embodiments. FIG. 14A illustrates a Raman spectra comparing vibrational features of S—S and C—C bonds in melt-diffused, 200° C. ampule, and 600° C. ampule S/C composites. FIGS. 14B and 14C illustrate tender X-ray absorption spectra (C K-edge and S K-edge, respectively) indicating differences in local sulfur environments. FIGS. 14D, 14E, and 14F illustrate XPS C 1s, S 2p, and O 1s spectra, respectively, showing binding energy shifts and chemical state variations.

FIGS. 15A-15E illustrate the electrochemical performance of S/C composite cathodes prepared via different infiltration strategies according to some embodiments. FIG. 15A shows the galvanostatic charge-discharge voltage profiles of conventionally melt-diffused composite, Ampule-200° C. and Ampule-600° C. samples at 0.1 C, showing initial capacities. FIG. 15B shows the C-rate performance of the three samples measured at various C-rates of 0.05, 0.1, 0.2, 0.3, 0.5, 1, and 2 C. FIG. 15C shows the Nyquist plots collected after a fully charged state of electrodes. FIGS. 15D and 15E show the long-term cycling stability test at 0.1 C and 1 C, respectively.

FIGS. 16A-16K illustrates the cyclic voltammetry (CV) and Li—PS diffusion current measurement results of sulfur cathodes prepared via different infiltration strategies according to some embodiments. FIGS. 16A-16C show the CV curves of conventionally melt-diffused S/C composite, Ampule-200, and Ampule-600 electrodes, respectively, measured at scan rates from 0.05, 0.1, 0.2, 0.5, and 1.0 mV s⁻¹. FIGS. 16D-16F illustrate the corresponding Randles-Sevcik plots (peak current i_{P} vs. v^{1/2}) for each electrode, with fitted slopes used to estimated the apparent D_{Li} of Li—S reaction. FIGS. 16G-16I illustrate the galvanostatic charge-discharge voltage profiles obtained during the shuttle current measurement. FIGS. 16J and 16K illustrate the chronoamperometric shuttle current measurement and its corresponding comparison, respectively, of the it^{1/2} vs. t^{1/2} plots for only 1000 s shuttle current measurement based on Cottrell analysis to evaluate Li—PS shuttle suppression.

### DETAILED DESCRIPTION

Detailed aspects and applications of the disclosure are described below in the following drawings and detailed description of the technology. Unless specifically noted, it is intended that the words and phrases in the specification and the claims be given their plain, ordinary, and accustomed meaning to those of ordinary skill in the applicable arts.

In the following description, and for the purposes of explanation, numerous specific details are set forth in order to provide a thorough understanding of the various aspects of the disclosure. It will be understood, however, by those skilled in the relevant arts, that embodiments of the technology disclosed herein may be practiced without these specific details. It should be noted that there are many different and alternative configurations, devices and technologies to which the disclosed technologies may be applied. The full scope of the technology disclosed herein is not limited to the examples that are described below.

The word “exemplary,” “example,” or various forms thereof are used herein to mean serving as an example, instance, or illustration. Any aspect or design described herein as “exemplary” or as an “example” is not necessarily to be construed as preferred or advantageous over other aspects or designs. Furthermore, examples are provided solely for purposes of clarity and understanding and are not meant to limit or restrict the disclosed subject matter or relevant portions of this disclosure in any manner. It is to be appreciated that a myriad of additional or alternate examples of varying scope could have been presented, but have been omitted for purposes of brevity.

While this disclosure includes a number of embodiments in many different forms, there is shown in the drawings and will herein be described in detail particular embodiments with the understanding that the present disclosure is to be considered as an exemplification of the principles of the disclosed methods and systems, and is not intended to limit the broad aspect of the disclosed concepts to the embodiments illustrated.

As the transportation industry shifts towards electric vehicles in an effort to reduce environmental impact, sustainable battery manufacturing will become critical for the development of a clean-energy economy in the US. Batteries will need improved performance while being less expensive and more environmentally sound to manufacture. The current state-of-the-art method for battery electrode manufacturing will be unable to meet the needs of the future on a number of fronts, including environmental impact, advancing electrode structure, and reduced manufacturing costs.

Batteries based on Li-ion technology typically utilize cobalt and nickel as part of the cathode. However, concentrated sources of cobalt and nickel used in Li-ion batteries are limited in supply and concentrated in specific geographic regions. The sourcing of cobalt and nickel is also associated with significant environmental and ethical concerns.

The present disclosure relates to lithium/sulfur (Li/S) battery technology, which has emerged as a promising alternative to conventional lithium-ion systems. Li/S batteries offer several key advantages that address the limitations of current Li-ion technology and have the potential to revolutionize the battery industry. Firstly, Li/S batteries may offer a theoretical specific capacity of up to 1675 mAh/g and a specific energy of up to 2600 Wh/kg, both considerably higher than traditional Li-ion batteries. Energy densities of this order can potentially extend the range of electric vehicles (EVs) and enhance the performance of portable electronic devices. Moreover, sulfur, the cathode material in Li/S batteries, is abundant, low-cost, and environmentally benign. The widespread availability of sulfur, a byproduct of the petroleum industry, ensures a sustainable and cost-effective supply chain. The high energy density, cost-effectiveness, and environmental sustainability of Li/S batteries position them as a leading candidate for future energy storage solutions. Their ability to provide superior performance, while addressing the limitations and concerns associated with current battery technologies, highlights their potential to transform various sectors, from electric vehicles to portable electronics.

Despite these advantages, Li/S batteries face several technical challenges that limit their practical application. In particular, the low electrical conductivity of sulfur and the dissolution of Li—PS lead to lower energy density and reduced cycle life. The intrinsic low electrical conductivity of sulfur severely limits its electrochemical performance, necessitating the use of conductive additives that can reduce the overall energy density. Additionally, the “Li—PS shuttle effect” occurs when Li—PS dissolve from the cathode into the electrolyte and migrate to the anode, where they are reduced and re-oxidized. This parasitic transport depletes active sulfur from the cathode and increases internal resistance, leading to capacity fading and a reduced cycle life in Li/S batteries.

In addition, sulfur undergoes significant volumetric change during lithiation and delithiation, leading to mechanical stress and degradation of the sulfur cathode structure. These limitations have hindered the practical application and widespread adoption of Li/S batteries within the emerging, clean-energy economy. Addressing these technical challenges remains essential for realizing the full potential of Li/S batteries in commercial applications.

One promising strategy to address the inherent challenges of Li/S batteries is the integration of sulfur into electrically conductive porous carbon to form a small sulfur particle encapsulated into the nano-sized pores of the carbon. However, conventional fabrication methods, such as melt-diffusion, where sulfur is melted and infiltrated into carbon pores, often result in incomplete pore filling, surface agglomeration, and the reformation of crystalline α-sulfur (α-S) domains. These crystalline domains exhibit poor redox kinetics and contribute to uneven electrochemical behavior. Nanoscale confinement can alter crystallinity in sulfur, potentially stabilizing non-crystalline or nanocrystalline phases. Yet, many S/C composites still display dominant α-S peaks in XRD, even when sulfur is believed to be well-dispersed. This discrepancy suggests that residual sulfur outside the porous host or poorly confined domains may be responsible. Moreover, amorphization is not guaranteed by dispersion alone and requires precise control over pore morphology, chemical purity, and thermal conditions during synthesis.

A fundamental factor in overcoming the inherent challenges of Li/S batteries and achieving improved cathode performance lies in the fabrication methods used to create the S/C composites. Advanced fabrication techniques are essential for ensuring uniform sulfur distribution throughout the carbon matrix while preventing large sulfur agglomeration. The present disclosure introduces a vapor-phase infiltration method for creating S/C composites, which enables uniform sulfur dispersion and stabilizes non-crystalline sulfur within desorbed porous carbon. These composites exploit the advantageous properties of nanomaterials to enhance electronic conductivity as well as chemical and structural stability of sulfur cathodes in Li/S batteries. The non-crystallinity or nano-crystallinity of sulfur within these composites can play a crucial role in enhancing the electrochemical performance of Li/S batteries. Unlike crystalline sulfur, which suffers from sluggish reaction kinetics and volumetric expansion during cycling, non-crystalline sulfur could exhibit improved reactivity and flexibility, which helps mitigate these issues. The nano-structured carbon matrix serves as an interconnected conductive network, significantly improving electron transport within the cathode and overcoming the inherently poor conductivity of sulfur. Additionally, the high surface area of the porous carbon ensures more uniform sulfur distribution, leading to higher sulfur utilization and improved electrochemical reactions. Nanoscale confinement of sulfur within the carbon matrix also plays a crucial role in mitigating the Li—PS shuttle effect described above. Moreover, the chemical bonding between sulfur and carbon further increases Li—PS immobilization, trapping them within the matrix and preventing their migration to the lithium anode through the electrolyte. Furthermore, the porous nature of the carbon matrix not only accommodates the volumetric expansion of sulfur during lithiation, reducing mechanical stress, but also preserves the structural integrity of the cathode.

One key aspect of this process is the desorption of porous carbon to effectively empty the pores, allowing for efficient sulfur infiltration. Proper pore desorption enhances the accessibility of the nano-sized carbon pores, ensuring maximum sulfur accommodation and promoting uniform sulfur distribution. Efficient utilization of nano-sized carbon pores is critical for controlling sulfur particle size and crystallinity. Such control helps prevent sulfur aggregation, which can lead to uneven reactions and reduced battery efficiency, as well as adverse mechanical effects from volume expansion. By facilitating efficient sulfur infiltration and ensuring uniform sulfur dispersion within the carbon matrix, these methods enable the creation of a well-dispersed sulfur phase, leading to consistent electrochemical performance and maximum sulfur utilization. This is especially important for preventing the formation of large sulfur clusters, which can hinder ion transport and reduce overall battery efficiency. These innovations, combined with the precise synthetic control over the composite structure, hold the potential to significantly improve the energy density, cycle life, and overall efficiency of Li/S systems. By enabling uniform sulfur distribution within the nano-sized carbon pores and controlling sulfur's crystallinity, these composites bring Li/S batteries closer to practical and commercial applications in energy storage technologies.

Disclosed herein is an S/C composite useful as a cathode material in Li/S batteries, as well as a system and method for fabrication of the S/C composite useful as a cathode material in Li/S batteries. According to some embodiments, the system and method for S/C composite fabrication comprises two phases to fabricate the S/C composite for use as an electrode material in a battery, such as a cathode in a Li/S battery: (1) a carbon powder desorption process, and (2) a sulfur incorporation process. The S/C composite may be in the form of a powder. For example, the S/C composite may include a carbon particle or small number of particles having sulfur disposed on a surface or in a nano-sized pore. As another example, the S/C composite may include a group of carbon particles having sulfur disposed on a surface or within nano-sized pores of the group. In some embodiments, the S/C composite may be a larger amount or mass of amorphous carbon powder having sulfur disposed within nano-sized pores and across a surface of the carbon. According to some embodiments, the amorphous carbon powder may be substantially amorphous, i.e., non-crystalline. According to further embodiments, the amorphous carbon powder may comprise both amorphous and crystalline carbon structures, and such variations are considered within the scope of the amorphous carbon powder disclosed herein. The composite powder may thereafter be enclosed for use as an electrode in a battery, such as the Li/S batteries disclosed herein.

Advantages of the disclosed method over conventional methods include removing trace impurities, such as oxygen, nitrogen and other organic compounds as well as moisture from the powder prior to vaporizing sulfur to form nanometer-size or nano-scale particles into the nano-scale pores, and onto a surface, of a desorbed amorphous carbon powder. This is accomplished without exposure to the surrounding environment. In so doing, the sulfur is finely dispersed into the pores and on the surface of the desorbed amorphous carbon powder. The finely dispersed sulfur bonds to the carbon powder, preventing the deleterious effects of the volumetric expansion of sulfur, the dissolution of intermediate Li—PS into the electrolyte during cycling, and lessening the effects of the inherently low conductivity of sulfur by its fine dispersion over and within the conductive carbon powder. In some embodiments, sulfur as a byproduct of the petroleum industry may be repurposed for use in the disclosed method, reducing environmental waste.

It should be noted that the system, method and S/C composite for use as a cathode in a Li/S battery as contemplated herein may also have applications beyond battery technology. While the following discussion is focused on the context of fabricating battery electrodes for rechargeable batteries, the system and method may be adapted for use in manufacturing other devices or components, both known in the art and as of yet undeveloped.

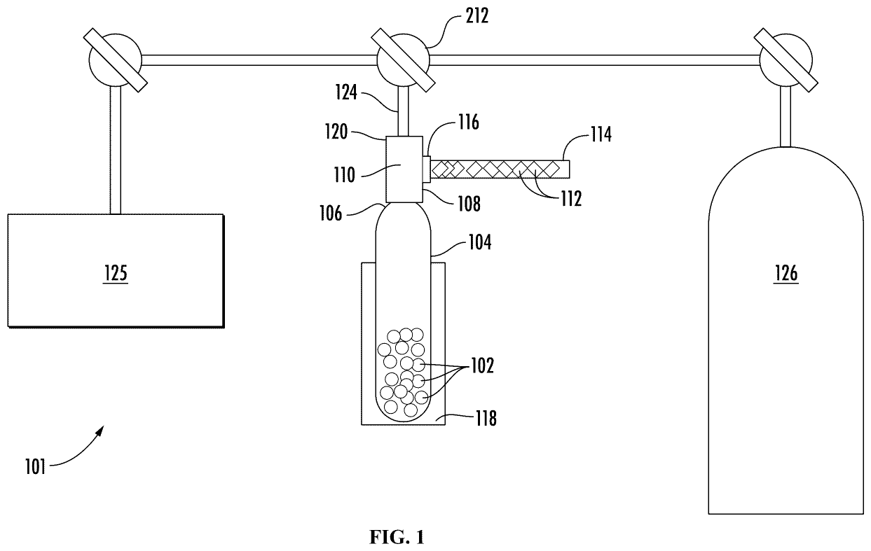

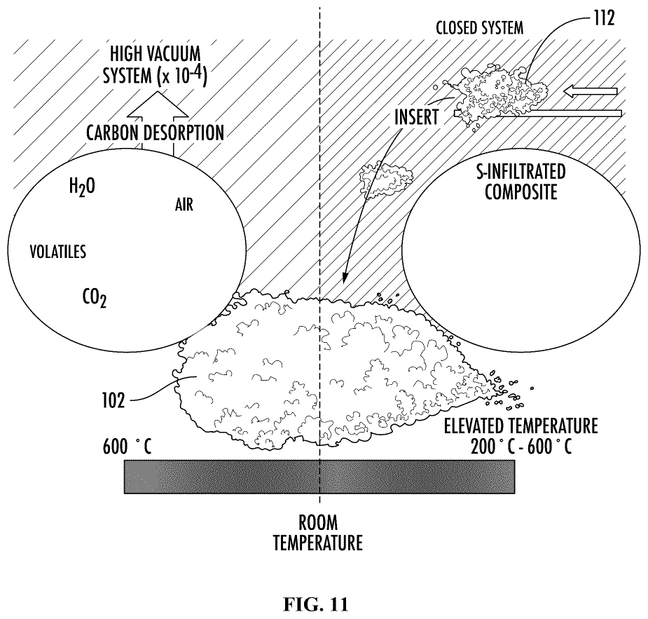

FIGS. 1-3 illustrate various non-limiting examples of implementations of the contemplated system and method for fabricating a S/C composite 100. Specifically, these figures show phases of the method (i.e., desorbing the carbon powder, a sealed container including the desorbed carbon powder and sulfur source, and sulfur incorporation into the desorbed powder). These phases are also illustrated in FIG. 11.

FIG. 1 illustrates a system 101 for the carbon desorption process according to the methods as disclosed herein. According to the methods, the carbon desorption process includes providing an amorphous carbon powder 102 and disposing the carbon powder 102 in a container 104, such as through the use of a long glass funnel. In some embodiments, the carbon powder 102 comprises a porous carbon black powder. The porous carbon powder 102 may have nanometer-size pores and a specific surface area of from about 300 m²/g to about 2000 m²/g, preferably from about 800 m²/g to about 1500 m²/g. The carbon powder 102 may have other specific surface areas in some embodiments. In some embodiments the carbon powder 102 may comprise Ketjen black, also referred to as carbon black.

According to various embodiments, the container 104 may comprise a heavy-wall silica glass container or a quartz container. In some embodiments, the container 104 may comprise a glass ampule. In further embodiments, the container 104 comprises a chemically inert, hermetic container. According to some embodiments, a volume of the container 104 may be filled with the amorphous carbon powder to from about 30% to about 60% capacity. For example, the container 104 may be filled to about 50% capacity. The container 104 may comprise a narrowed portion or neck 106 which is connected to a bottom vertical port 108 of an O-ring union tee vacuum fitting 110. The tee 110 may be held in place by means of a three-finger clamp secured to a ring stand.

The method as disclosed further comprises providing a sulfur source 112 gaseously coupled to the amorphous carbon powder 102 in the container 104 through a staging tube 114. According to some embodiments, the sulfur source 112 may be ultra-high purity or high purity, and may comprise sulfur chips, a sulfur block or piece, sulfur granules or sand, or a sulfur powder. The sulfur source 112 may be disposed in the staging tube 114 such that the staging tube 114 has one end closed and the opposite end connected to a horizontal side port 116 of the O-ring union tee vacuum fitting 110. The staging tube 114 holds the sulfur 112 under inert gas and vacuum but away from the hot zone of the heat source 118 during thermal desorption of the carbon 102, thereby preventing sublimation of the sulfur 112. Thus, the staging tube 114 acts as a thermally isolated storage section for the sulfur 112. In some embodiments, the staging tube 114 comprises a standard-wall silica glass tube. In further embodiments, the staging tube 114 comprises quartz or similar materials.

The upper vertical port 120 of the O-ring union tee 110 is then connected to a high-vacuum gas-handling manifold 122 by means of a flexible stainless steel bellows tube 124 and additional O-ring union adapters as needed for the vacuum-compatible connections between the upper port 120 of the tee 110 and the manifold 122. The method further comprises connecting the vacuum source 125 (such as a vacuum pump) and an inert gas supply 126 to the container 104 and staging tube 114. In some embodiments, the inert gas comprises argon.

In some embodiments, the method includes slowly evacuating the container 104 and staging tube 114 to remove ambient air and surface adsorbed gaseous species from the amorphous carbon powder 102 and the sulfur source 112. After a period of time at vacuum (e.g., from about 15 minutes to about 45 minutes, such as 30 minutes), the method comprises backfilling the container 104 and staging tube 114 with a high purity or ultra-high purity inert gas, such as ultra-high purity argon gas, to a pressure of about ⅔ atmosphere absolute (ATA).

In some embodiments, the method further includes desorbing the amorphous carbon powder 102 according to the following desorption process. According to the method, desorption is facilitated by heating the container 104 at a location proximal the amorphous carbon powder 102. Heating the container 104 includes positioning a heat source 118 such as a furnace around or proximal the container 104 such that a hot zone of the heat source 118 provides heat proximal to the amorphous carbon powder 102.

Next, the method comprises evacuating the amorphous carbon powder 102 in the container 104 and the sulfur source 112 in the staging tube 114 to from about ⅔ ATA to about ⅓ ATA such that gaseous species and moisture are at least partially removed from the amorphous carbon powder 102. Lastly, as part of the carbon desorption process, the method comprises backfilling the container 104 to about ⅔ ATA with a high purity inert gas. In some embodiments, the desorption process is repeated by heating the container 104 until a predetermined desorption temperature is reached to form a desorbed amorphous carbon powder 102. The desorption temperature may be equal to or greater than a sulfur infiltration temperature reached in the sulfur infiltration step described in more detail below. In some embodiments, the container 104 is then cooled to room temperature under the high purity inert gas.

Due to the high surface area of the amorphous carbon powder 102, it may contain moisture and other surface-adsorbed volatiles which are present in large quantity. The disclosed evacuation/backfill procedure desorbs and removes moisture and other surface-adsorbed volatiles from the powder 102 such that it is free of, or substantially free of moisture and adsorbed, volatile organic species. In addition, the volatiles and moisture are a source of contamination which adversely affects the purity of the final product and its overall sulfur content. If not removed at the outset, such volatiles will generate very high internal pressure in the sealed container 104 when it is later heated to induce uptake of the sulfur 112 by the carbon 102. The disclosed evacuation/backfill procedure may be repeated until no further desorption of moisture or other volatile organic species (or a negligible amount of desorption) occurs from the carbon powder 102 at the predetermined desorption temperature, which is the same as, or substantially the same as, a high temperature used for sulfur uptake into the carbon. In so doing, the buildup of excessive pressure, leading to failure or explosion of the sealed container 104, may be prevented.

The carbon powder 102 in the container 104 may be slowly heated at about 5° C./min to about 15° C./min. At each 50° C. increment in temperature, the heating ramp is paused, and the system is evacuated from ⅔ atmosphere absolute to ⅓ atmosphere absolute, then backfilled to ⅔ atmosphere absolute (as discussed above). The inert gas (e.g., argon) serves to conduct heat to the carbon and carry desorbed volatiles, which are evacuated with the argon. This partial evacuation/backfill cycle may be repeated any number of times to ensure complete removal of volatiles at each intermediate temperature. Repetition of the evacuation/backfill cycle may be a function of the amorphous carbon specific surface area. In some embodiments, the procedure may be repeated between 5 and 15 times, dependent upon the specific surface area of the carbon powder 102. Typically, the procedure may be repeated about 10 times to fully desorb the carbon.

The ramp is then continued to the next 50° C. intermediate temperature, and the evacuation/backfill procedure is repeated. In some embodiments, the evacuation/backfill procedure is repeated 10 times at each temperature. Desorption is an activated process which can occur suddenly at various threshold temperatures, depending on the desorbing species and the strength of its bonding with the porous carbon 102. The primary goal of this sequence is to remove moisture from the carbon 102. In this way, desorption can be controlled to avoid sudden turbulence that would otherwise disturb the carbon powder 102.

The carbon powder 102 in the container 104 may be slowly heated at about 5° C./min to about 15° C./min, to a final, high temperature of from about 400° C. to about 800° C., or from about 500° C. to about 700° C. According to some embodiments, the carbon powder 102 in the container 104 may be heated to a high temperature of about 600° C., each under argon gas at sub-ambient pressures as controlled by a high vacuum gas handling manifold 126. Where the container 104 comprises a portion extending outside a hot zone of the heat source 118, that portion may be heated with a heat-gun or similar device to desorb moisture from the interior walls of the container 104. According to various embodiments, the high temperature is a predetermined temperature that is high enough such that the powder 102 is substantially free of moisture, adsorbed and volatile species, and other impurities such as oxygen and nitrogen.

Heating the powder 102 to a desorption temperature equal to or greater than the sulfur infiltration temperature as part of the subsequent sulfur infiltration step prevents generating excessive internal pressure, and possible detonation of the container 104. In some embodiments, the porous carbon powder 102 is fully desorbed at a temperature at least equal to the sulfur infiltration temperature at which the sealed container 104 is later heated to induce uptake of the sulfur 112 by the carbon 114. In some embodiments, a temperature of 600° C. is a suitable temperature, as long as the carbon powder 102 is subject to high vacuum at this temperature to confirm desorption is complete. In some embodiments, other combinations of pressure, time and temperature are used to achieve full desorption.

After full desorption is achieved, the method includes cooling the container 104 to room temperature under the high purity inert gas by removing the container 104 from the furnace or heat source 118.

The system and method for fabrication of the disclosed S/C composite 100 as disclosed utilizes the previously described desorption process for carbon desorption before sulfur infiltration. The thermal desorption of carbon under controlled pressure and temperature conditions removes moisture and surface-adsorbed volatiles, which prevents contamination and excessive internal pressure during sulfur infiltration. This control leads to a cleaner synthesis process and a higher purity product. The disclosure presents a new system 101 for sulfur infiltration and thermal desorption in carbon materials, uniquely designed to operate under vacuum or inert gas conditions while avoiding contamination or exposure to unwanted gaseous species.

As part of the system 101, the staging tube 114 advantageously maintains the sulfur 112 under inert gas and vacuum, and outside of the hot zone of the heat source 118 during thermal desorption of the amorphous carbon powder 102. Heating sulfur 112 under vacuum or inert gas would cause the sulfur 112 to sublime away from the carbon powder 102 without infiltrating the pores or depositing on the surface of the powder 102. The staging tube 114 also provides for convenient, in-situ transfer of sulfur 112 to the container 104 after the fully desorbed carbon 102 is at room temperature. The in-situ transfer using the staging tube 114 as part of the system and method, avoids having to transfer the container 104 to an inert atmosphere glovebox for addition of sulfur 112 after the carbon 102 is fully desorbed, without re-exposure of the carbon powder 102 to any gaseous species. This streamlines the process while preserving the integrity of the desorbed carbon 102 by keeping the desorbed carbon 102 free from re-exposure to atmospheric gases during transfer of sulfur 112 to the desorbed carbon 102.

Disposing the sulfur source 112 over the desorbed amorphous carbon powder 102 in the container 104 is accomplished by rotating the tee 110 such that the sulfur-staging tube 114 tilts upward and the sulfur source 112 slides down the tube 114, falling through the tee 110 into the container 104 and on the surface of the fully desorbed carbon powder 102. Thereafter, the container 104 may be evacuated to a vacuum of for example 9×10⁻⁵ torr, although higher or lower vacuums may also be used. According to the method, the amount of sulfur 112 distributed within the nanopores of carbon 102 is limited by the void volume of the carbon host. Precise control of pressure and temperature within the container 104, both during carbon desorption and sulfur infiltration, helps provide efficient sulfur infiltration into the nano-scale pores.

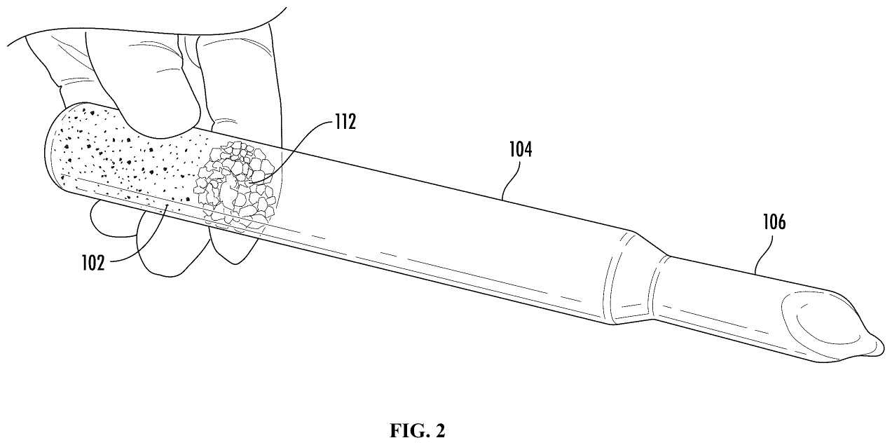

To prevent ingress of volatile organics, moisture or impurities into the desorbed carbon powder 102, the container 104 may be sealed at a location along the narrowed portion or neck 106 below the staging tube 114 while under inert gas. In some embodiments, sealing the container 104 may be done by a hand-held hydrogen/oxygen glass blowing torch. Other approaches for sealing the container 104, which prevent exposure to the outside environment and are useful as part of the sulfur infiltration process described herein, may also be used. In some embodiments, sealing of the container 104 comprises a hermetic seal. FIG. 2 illustrates one embodiment of a sealed container 104 after the carbon desorption process and before beginning the sulfur infiltration process, depicting the amorphous carbon 102 and sulfur source 112 disposed over the carbon 102. While a glass container 104 sealed by blow torch heating is depicted, other embodiments of the container 104 and methods of sealing are possible, in particular when implemented in a manufacturing environment, and are contemplated as part of the disclosure.

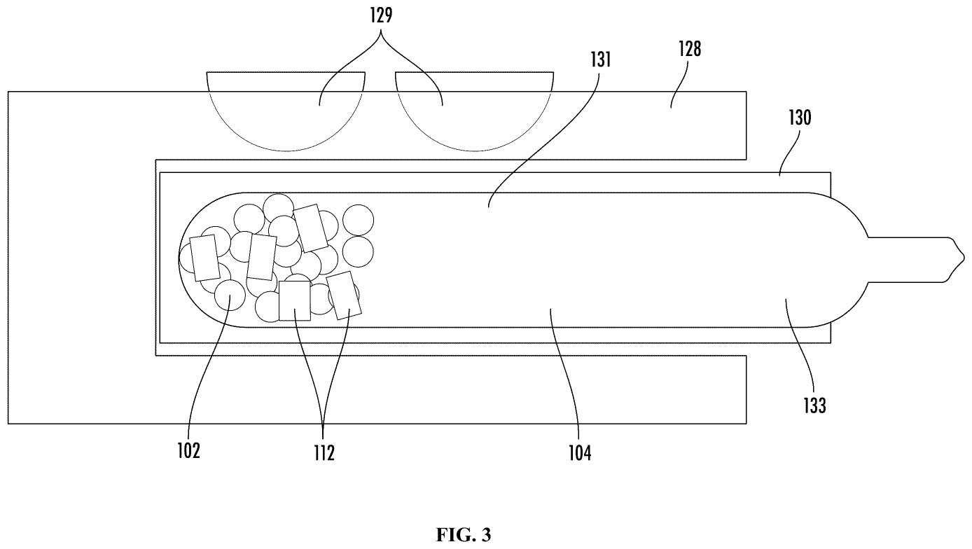

After the sulfur 112 has been transferred into the container 104 and the container 104 sealed, the method may continue with a sulfur infiltration process into nano-sized pores of carbon 102. In some embodiments, as shown, for example, in FIG. 3, the sealed container may be placed in a heat source 128 (such as a box furnace) or similar apparatus and heated. In some embodiments, the heat source 128 is the same as was used as the heat source 118 described above. In some embodiments, the heat source 118 and the heat source 128 are separate components. In some embodiments, the sealed container 104 is first placed in a furnace core tube 130. The furnace core tube 130 may be made of low-density aluminosilicate. In some embodiments, the furnace core tube 130 is slightly longer than the sealed container 104. The ends may be plugged with aluminosilicate wool. The wool secures the sealed container 104 in the tube 130 and thermally insulates the ends of the container 104. The low-density ceramic tube 130 has good resistance to thermal shock compared to fully dense alumina, for example. The ceramic tube 130 protects the heat source 128 against possible detonation of the container 104 and thermally insulates the entire container 104 against temperature gradients.

In some embodiments, the sealed container 104 inside the furnace core tube 130 is loaded into a heat source 128 (such as a box furnace) and heated. In some embodiments, the sealed container 104 is heated at a controlled ramp rate. The heating rate may be, for example, from about 5° C./min to about 15° C./min (about 10° C./min) until the temperature reaches a target temperature. In some embodiments, the sealed container may be maintained at target temperatures of 200° C., 400° C., or 600° C. for approximately 12 hours. Other temperatures may also be used (e.g., about 200-800° C.). During this process, the sulfur 112 vaporizes and deposits on the surface and infiltrates the nanopores of the carbon 102. When loading the sealed container 104 into the heat source 128, the side with the sample (the carbon and sulfur) may be closer to the heating element 129 of the heating source 128 and the empty side may be disposed farther from the heating source 128. The position of the heating element 129 with respect to the container 104 causes the sample to be positioned in a high temperature zone 131 while the empty side is positioned in a low temperature zone 133, where the temperatures in the low temperature zone 133 is lower than the temperatures in the high temperature zone 131. This arrangement allows any extra sulfur 112 to be condensed far away from the carbon-sulfur composite 100, instead of aggregating outside the sulfur-infused carbon powder.

After the sealed container 104 is held at target temperatures of 200° C., 400° C., or 600° C. for approximately 12 hours, the heat source 128 may be powered off. This allows the sealed container 104 to cool gradually to room temperature (e.g., over an additional 12-hour period). As noted above, a thermal gradient provided across the sealed container (such as by varying the amount of thermal insulation or disposing close to, or away from, a heat source) in the heat source 128 provides for the desorbed carbon powder 102 to reach the sulfur infiltration temperature at one high temperature portion of the sealed container 104 such that the sulfur 112 vaporizes and deposits on the surface and infiltrates the nanopores of the carbon 102, and condensation of sulfur 112 occurs on an interior of the sealed container 104 which is farther away from the heat source 128 and at a lower temperature, rather than aggregating on the desorbed carbon powder 102. Stated another way, residual sulfur 112 that is not disposed within the nanometer-size pores and remains as vapor condenses on the walls of the sealed container 104 outside of the desorbed amorphous carbon powder 102 in the low temperature region (e.g., where there is no thermal insulation).

The method disclosed above is also illustrated in FIG. 11, which shows the carbon desorption process on the left and the sulfur infiltration process on the right. As described above, in some embodiments, the carbon 102 is cooled to room temperature between the carbon desorption process and the sulfur infiltration process.

The disclosed method prevents sulfur agglomeration or aggregation from forming on an external surface of the nano-scale S/C composite 100, external to the nanopores. Accordingly, the system and method as disclosed herein provides for the formation of a S/C composite 100 which is free of, or substantially free of, sulfur agglomerates and aggregates. The sulfur disposed at a nano-scale in the S/C composite 100 comprises nanometer-scale sulfur which may be non-crystalline, i.e., amorphous, and/or nanocrystalline in structure. The sealed container 104 is thereafter unsealed in a controlled manner such that the nano-scale S/C composite material 100 is undisturbed and separate from the residual sulfur on an opposing end of the container. For example, the sealed container 104 may be opened by scoring the neck, wrapping the score with parafilm and breaking the neck at the score. The parafilm slows the in-rush of air to avoid disturbing the sulfur-infused carbon powder. The contents of the container 104 may then be collected for further analysis.

Thermodynamically, system pressure and temperature are the most influential parameters during the sulfur infiltration process. The disclosed system and method enhances sulfur infiltration into nanoporous carbon, while preventing sulfur agglomeration outside the pores by precisely controlling temperature and pressure. The container-based method includes a closed reactor system of the sealed container 104 as part of the method, and enables modulation of the initial internal pressure, which enhances the mobility of molten sulfur or sulfur vapor into the nanopores of the carbon matrix as the process begins at low pressure. The closed reactor system allows for high-temperature processing, even exceeding the vaporization point of sulfur, thereby improving the uniformity of sulfur distribution within the pores and creating new chemical bonds between carbon 102 and sulfur 112. Additionally, by creating a temperature gradient during the cooling phase, excess sulfur 112 that cannot be accommodated within the nanopores is efficiently removed from the S—C composite 100. The disclosed method is a controlled synthesis approach that minimizes sulfur agglomeration, optimizes sulfur loading, and significantly improves the electrochemical performance of Li/S batteries. In addition, the confinement of sulfur 112 within the carbon matrix 102 helps to immobilize Li—PS, which is a major cause of capacity fading and poor cycle life in conventional Li/S batteries. The method thus enhances the cycle stability and Coulombic efficiency of Li/S battery technology.

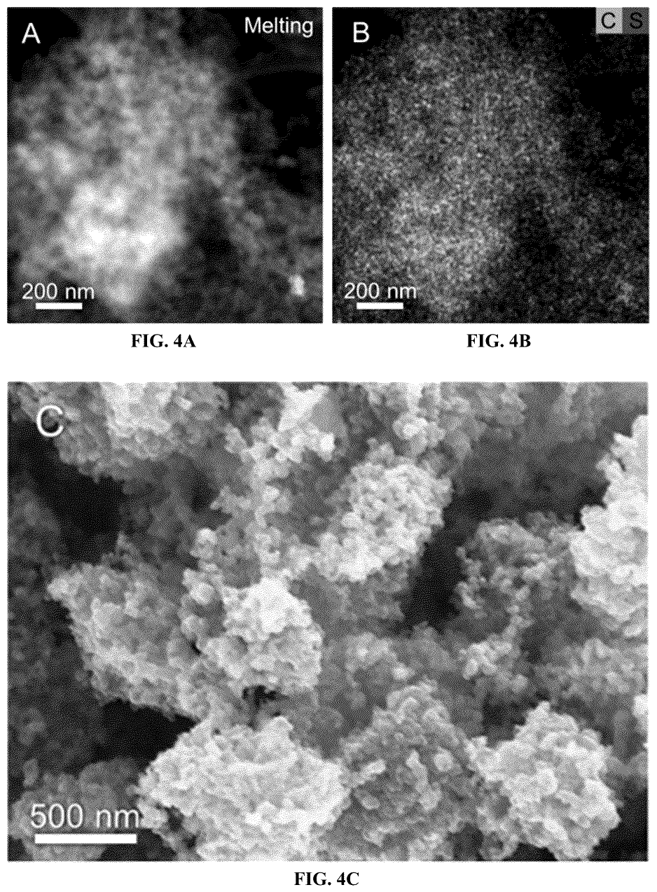

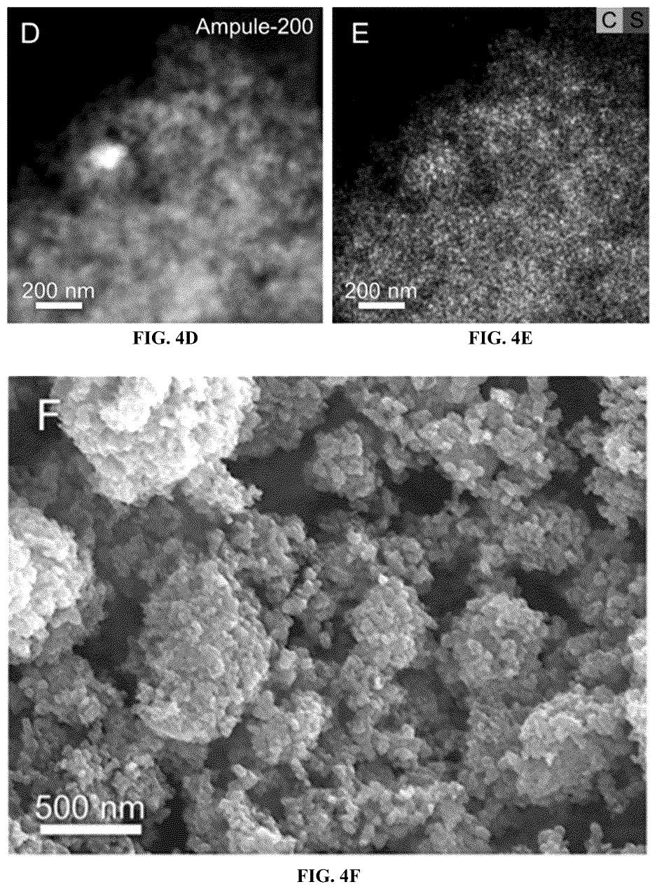

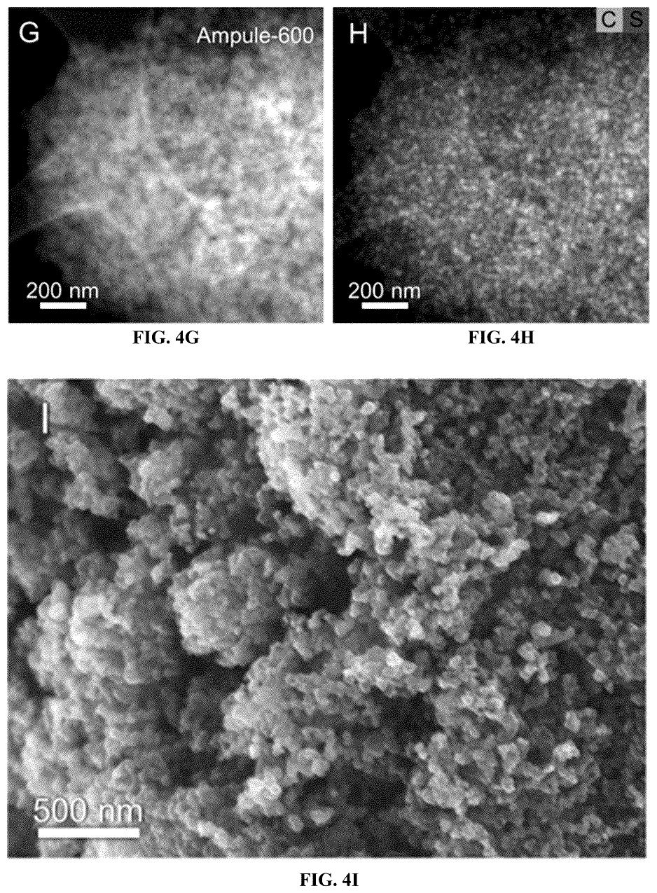

FIGS. 4A-4I are SEM images illustrating the effect of different infiltration methods and temperatures on sulfur distribution within the highly porous carbon powder or carbon matrix. FIGS. 4A-4C show an embodiment of the S/C composite prepared using a conventional tube furnace with an infiltration temperature of 155° C. FIG. 4A shows a TEM-HAADF image, FIG. 4B depicts TEM-EDS elemental mapping, and FIG. 4C shows an SEM image of the S/C composite synthesized via a conventional melt diffusion process. The S/C composite prepared with the infiltration temperature of 155° C. exhibits significant sulfur aggregates or agglomerates on the exterior of the porous carbon. This is because the highly porous carbon cannot desorb well under these conditions, leaving gas residues in the micropores which impede the sulfur infiltration.

FIG. 4D shows a TEM-HAADF image, FIG. 4E depicts TEM-EDS elemental mapping, and FIG. 4F shows an SEM image of the S/C composite synthesized via the disclosed method, and heating to an infiltration temperature of 200° C. As shown by FIGS. 4D-4F, the container heated to the infiltration temperature of 200° C. displays obvious sulfur aggregation within the S/C composite particles.

In contrast with the aforementioned results, the HAADF, EDS elemental mapping images of the S/C composite prepared according to the disclosed methods, using an infiltration temperature of 600° C. (as seen in FIGS. 4G-4I) illustrates the successful incorporation, at a nano-scale, of sulfur within the porous carbon matrix without significant sulfur aggregation.

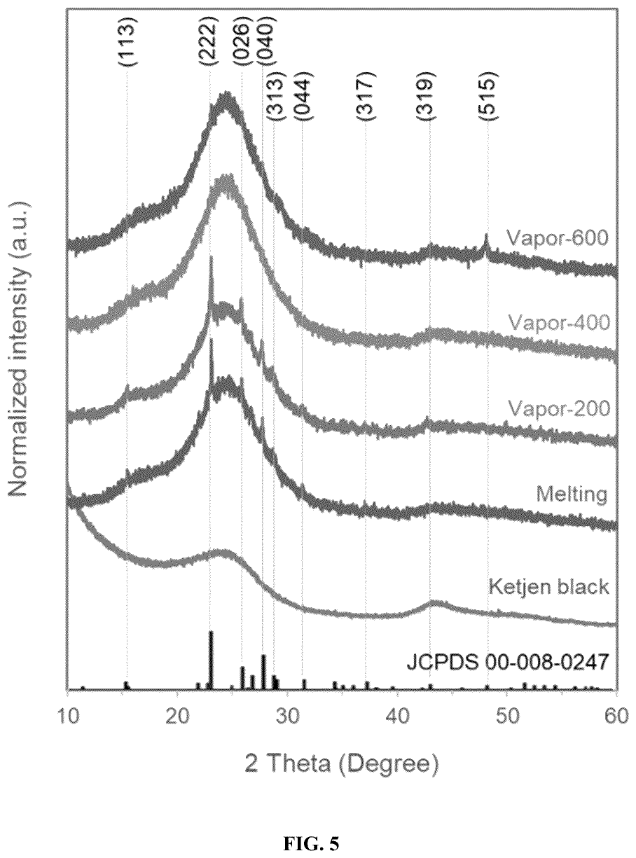

FIG. 5 illustrates XRD analysis results showing the crystallinity of sulfur in different fabricated S/C composites. Compared to crystalline sulfur from the XRD reference standard (JCPDS 00-008-0247), the melt-diffused S/C composite and the S/C composite formed at 200° C. each exhibit strong XRD peaks associated with sulfur, indicating the presence of crystalline sulfur. An S/C composite with a sulfur infiltration temperature of 400° C. was prepared in addition to that prepared at 600° C. according to the methods as disclosed. The S/C composites prepared at 400° C. and 600° C. do not show peaks corresponding to crystalline sulfur. Thus, the S/C composites prepared at 400° C. and 600° C. include nanometer-scale sulfur comprising non-crystalline and/or nanocrystalline sulfur.

In some embodiments, the container-based method for fabrication of the S/C composites facilitates the formation of both non-crystalline and nano-crystalline sulfur within the nano-scale pores of the carbon matrix, as well as finely distributed on the surface of the composites. These forms of sulfur can mitigate challenges associated with crystalline sulfur, such as volume expansion and sluggish electrochemical kinetics in Li/S batteries. The presence of non-crystalline and nano-crystalline sulfur enhances the mechanical integrity, surface reactivity, and electrochemical performance of the sulfur cathode, ultimately leading to improved battery performance, longevity, and cycle stability.

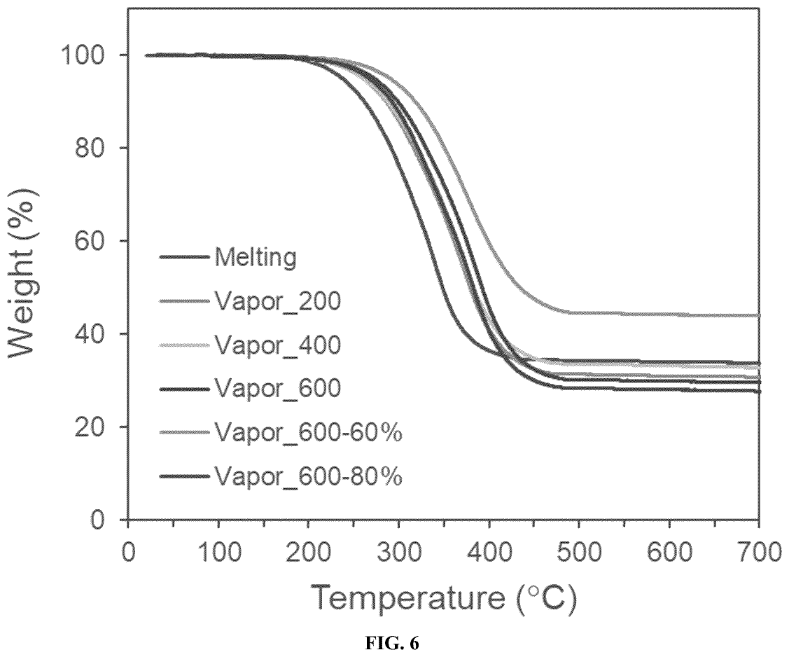

Samples of the S/C composites were heated to target temperatures of 200° C., 400° C., and 600° C. for TGA measurement as shown in FIG. 6. Samples of S/C composites having 60% and 80% by weight of sulfur were also prepared for measurement (both of which were measured at 600° C.). The TGA results illustrate that the S/C composites demonstrated approximately the same content of sulfur in each. These results, combined with the XRD results, demonstrate that the method, based upon use of a sealed container, successfully leads to infiltration of sulfur into nano-sized pores and prevents the nucleation and growth of crystalline sulfur within the S/C composite structure. These results highlight the efficacy of the disclosed container method, particularly at higher temperatures, in achieving uniform sulfur distribution and preventing sulfur aggregation within the desorbed carbon host.

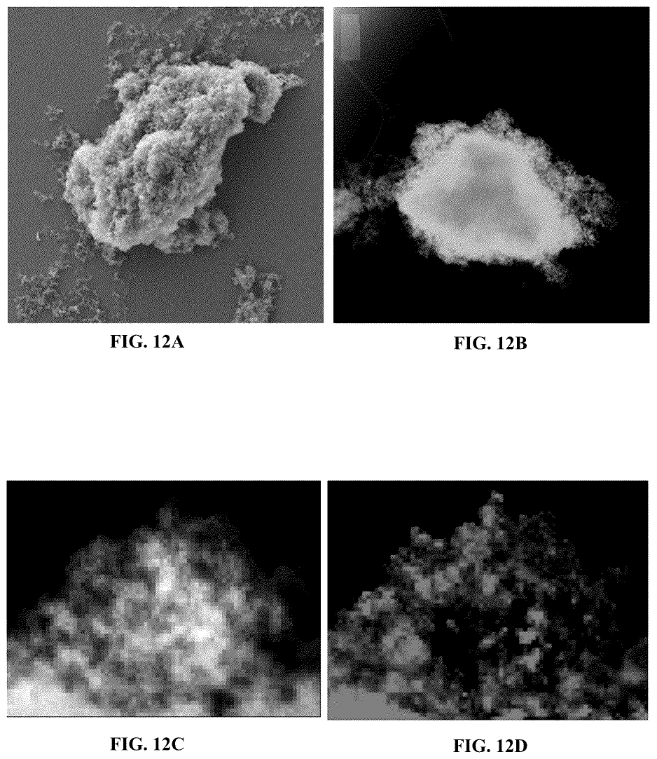

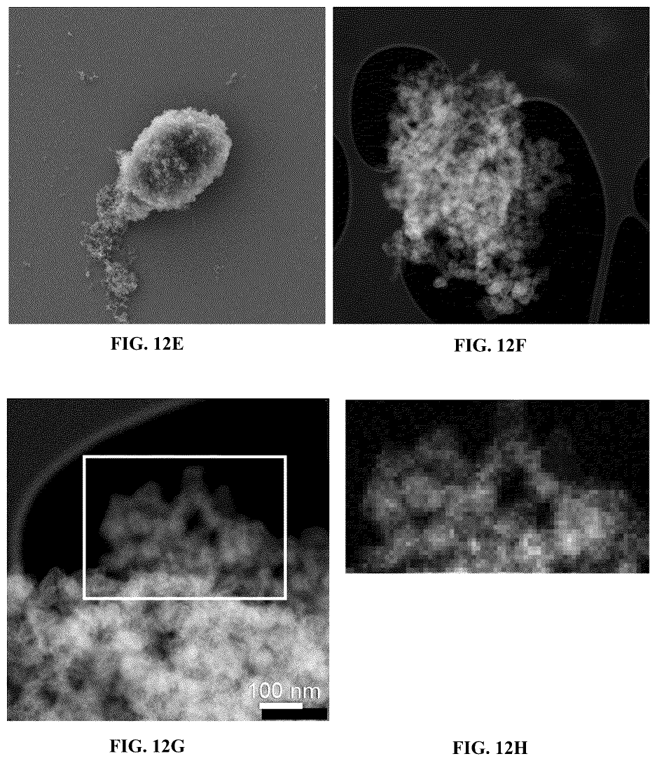

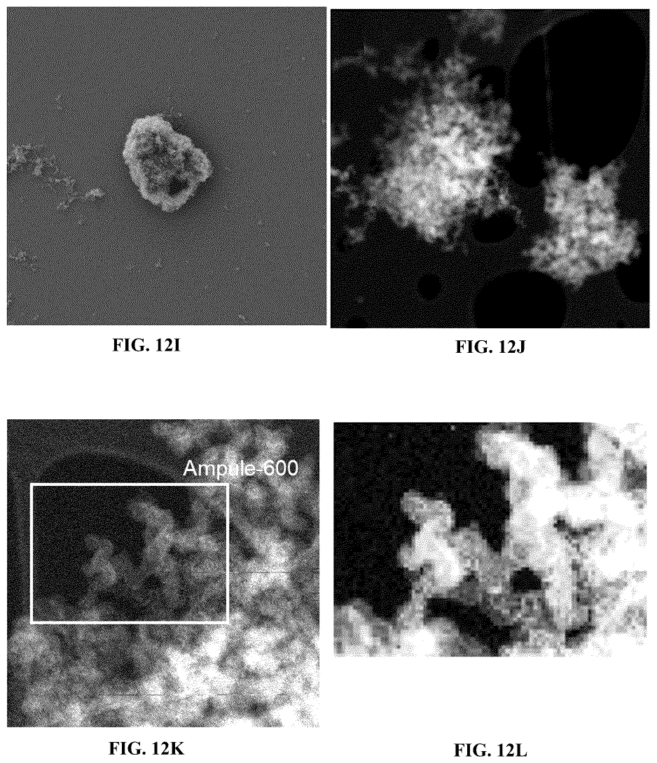

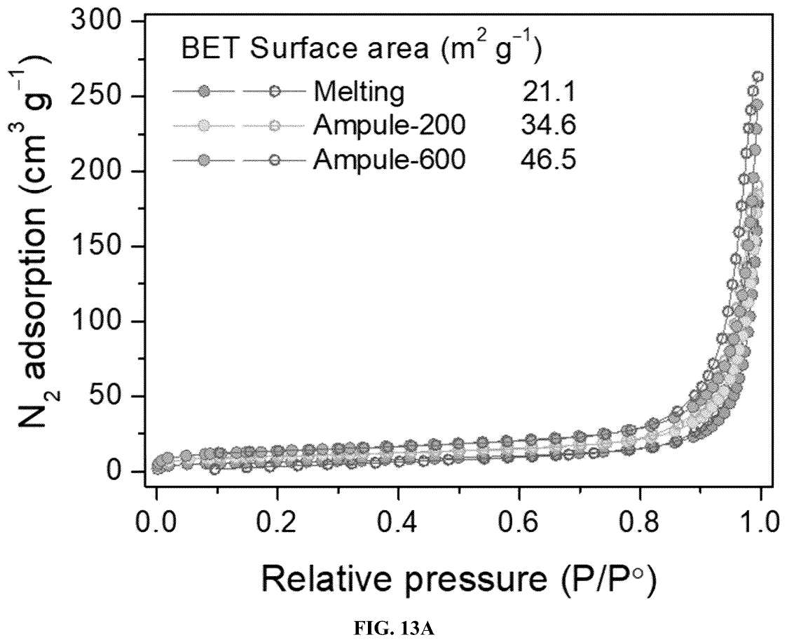

FIGS. 12A and 12B illustrate surface area analysis and pore size distribution results of the various S/C composites. The Brunauer-Emmett-Teller (BET) surface area analysis (FIG. 12A) and pore size distribution (FIG. 12B) of the melt-diffusion composite, the S/C composite heated to the infiltration temperature of 200° C., and the S/C composite heated to the infiltration temperature of 600° C. reveal similar N₂ adsorption/desorption characteristics. However, their mesopore (2-50 nm) and macropore (>50 nm) volume distributions differ significantly, with the S/C composite heated to 600° C. showing a notably larger pore volume in these size ranges.

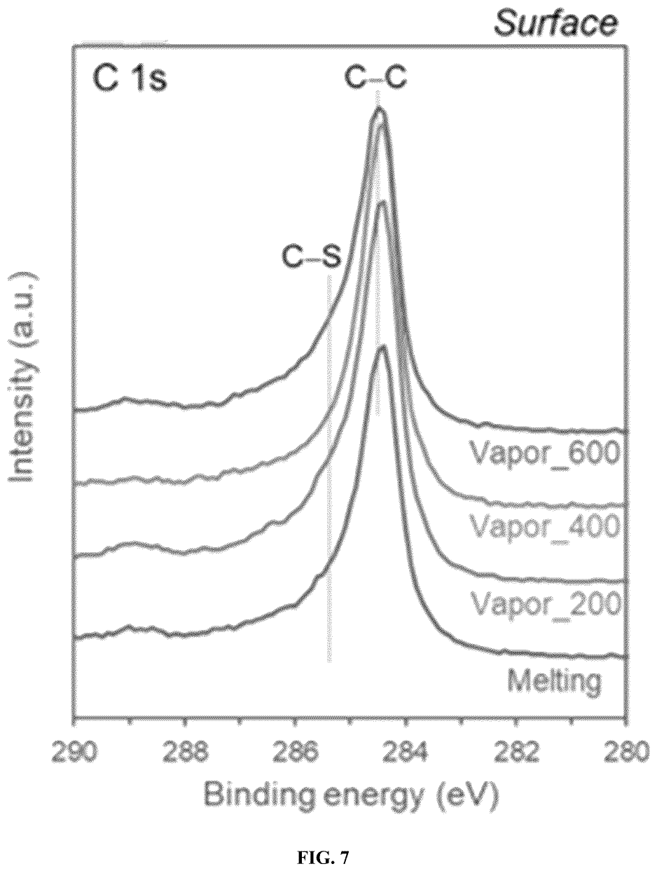

The XPS results as shown in FIG. 7 provide insights into the surface chemistry of the S/C composites. On the outermost surface of all composite particles, strong C—C and C—S binding energies are observed, indicating the presence of both carbon and sulfur interactions. The C 1s spectra show prominent peaks for C—C and C—S bonds across all samples, with the sulfur-carbon composite formed at 600° C. displaying more pronounced C—S signals, demonstrating the formation of C—S bonding as a consequence of the disclosed method and synthesis process.

The melt diffusion sample and the various sulfur-carbon composites were fabricated into 2032 coin-type Li/S batteries, incorporating a Celgard 2400 separator and an electrolyte comprising 1M lithium bis(trifluoromethanesulfonyl)imide (LITFSI) and 1 wt. % lithium nitrate (LINO₃) in dioxolane/dimethoxyethane 50/50 v/v (by volume).

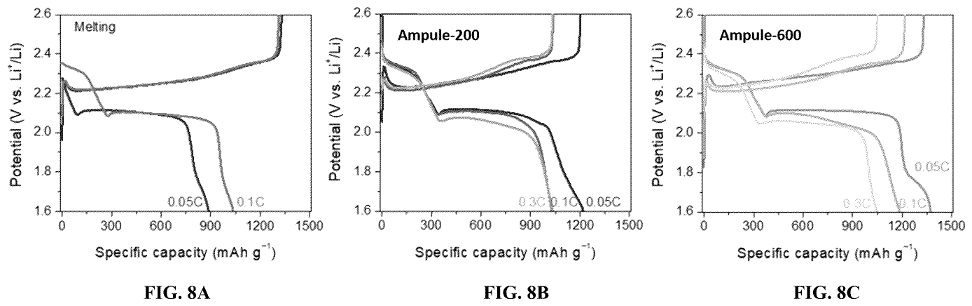

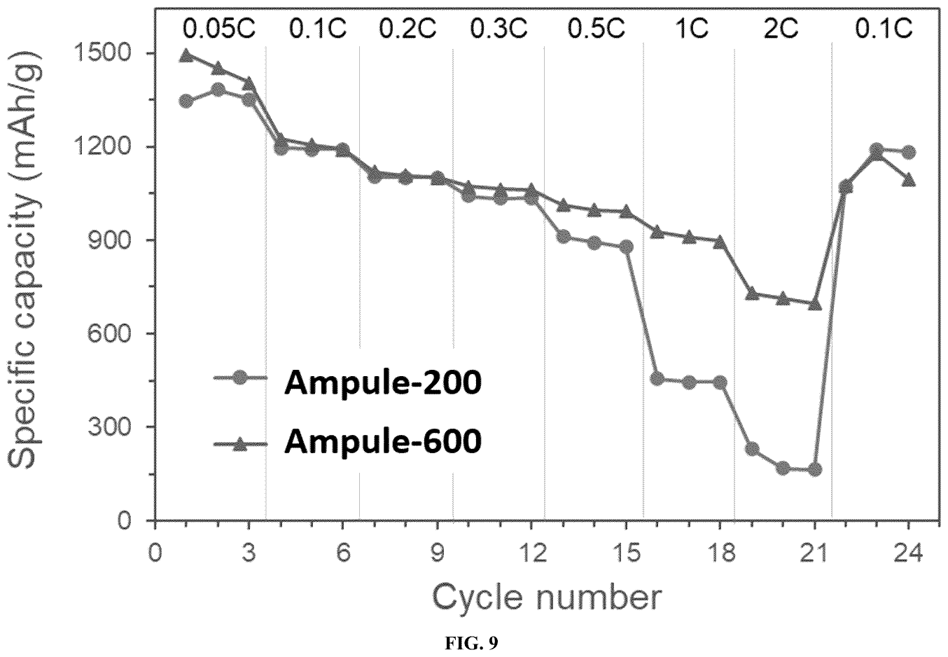

FIGS. 8A-8C illustrate galvanostatic charge and discharge performance of the melt diffusion cathode and the 200° C. and 600° C. S/C composite cathodes in the 2032 coin-type Li/S batteries, and FIG. 9 shows a rate capability test of the Li/S batteries. Between the S/C composite cathodes, the 600° C. S/C composite cathode exhibited the highest specific capacity at the tested C-rates (1 C=1675 mA/gS). The C rates indicate the charge and discharge rates of a battery. The trend is more obvious when it comes to high C-rate 1 C and 2 C rate, where the 600° C. S/C composite cathode shows specific capacities of 950 and 750 mAh/g. By contrast, the melt diffusion cathode showed a significantly lower specific capacity of 450 and 400 mAh/g. Li/S batteries utilizing the S/C composites prepared using the disclosed method exhibit high specific capacities, particularly at high C-rates, indicating superior performance under demanding conditions. The disclosed system and method enables the formation of S/C composites to form cathodes which deliver excellent energy densities and maintain long cycle lives, making them promising candidates for next-generation energy storage applications, particularly in electric vehicles and portable electronics.

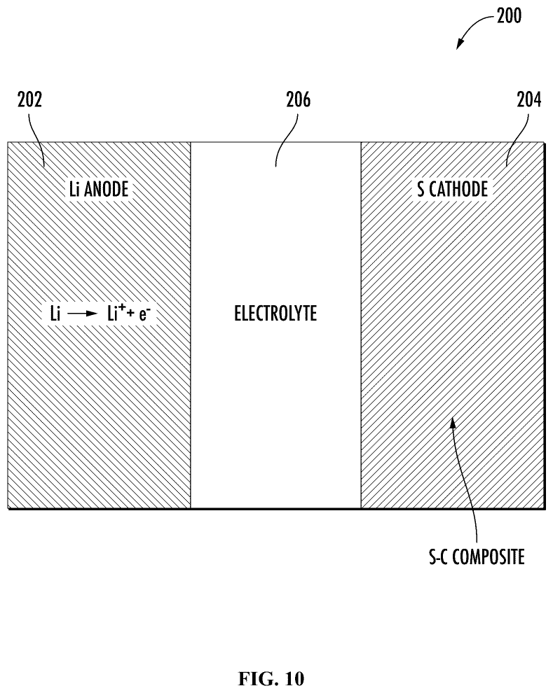

FIG. 10 illustrates an exemplary Li/S battery 200 according to embodiments of the disclosure. The Li/S battery 200 comprises a lithium anode 202 and a cathode 204 that comprises the S/C composite 100. An electrolyte 206 is positioned between the anode 202 and the cathode 204.

### EXAMPLES

To enable homogeneous sulfur infiltration into nanostructured carbon, a vapor-assisted ampule synthesis method was employed under high vacuum and elevated temperature using a sulfur-carbon (70 wt. % elemental sulfur and 30 wt. % Ketjenblack EC-600JD). The ampule-based synthesis method uniquely enables in-situ sulfur infiltration under sealed, low-pressure conditions immediately after carbon desorption, without breaking vacuum or exposing the material to air. After high-temperature desorption of Ketjenblack, the system is cooled to room temperature while maintaining vacuum, allowing direct introduction of sulfur through a staging tube and subsequent sealing of the quartz ampule with a torch, thereby completing the closed system. This configuration preserves the fully desorbed state of the carbon, prevents sulfur sublimation and contamination, and ensures uniform nanoscale sulfur incorporation, offering a level of purity and confinement control unattainable by conventional open or glovebox-based methods. The sealed ampule is then subject to heat treatment for sulfur infiltration at 200° C. or 600° C., enabling infiltration through both vapor and melt-phase transport. For comparison, a conventional S/C composite was also prepared by directly heating a sulfur-Ketjenblack physical mixture at 200° C. under flowing Ar gas without vacuum pre-treatment. This control sample was used to evaluate the impact of vapor-phase infiltration with pore cleaning on sulfur distribution and electrochemical performances.

The differing synthesis environments between vapor-assisted and melt-diffused samples were expected to markedly affect the spatial distribution and structural state of sulfur. As shown in FIG. 5, XRD patterns confirmed this distinction: sharp α-S reflections were evident in the conventional and 200° C. samples, whereas the 600° C. sample exhibited a broad amorphous profile devoid of long-range sulfur crystallinity, indicating successful amorphization via nanoconfinement and vapor-phase transport. SEM analysis revealed pronounced morphological differences (FIGS. 12A, 12E and 12I). The melt-diffused sample exhibited severe particle agglomeration and wide size distribution, while the 200° C. vapor-infiltrated sample displayed intermediate dispersion. In contrast, the 600° C. sample showed uniformly dispersed particles with minimal aggregation, implying that sulfur distribution strongly governs interparticle cohesion. Quantitatively, the melt-diffused composite exhibited the highest tapped density (0.42 g cm⁻³), consistent with its agglomerated morphology. HAADF imaging and EELS elemental mapping further corroborated these trends (FIGS. 12B-12D, 12F-12H and 12J-12L). In the melt-diffused composite (FIG. 12D), sulfur was concentrated on external surfaces, promoting particle fusion. The 200° C. vapor-infiltrated composite (FIG. 12H) showed improved but still partial surface localization. In contrast, the 600° C. composite (FIG. 12L) displayed highly uniform sulfur distribution confined within the porous carbon framework, consistent with the homogeneous morphology observed in SEM.

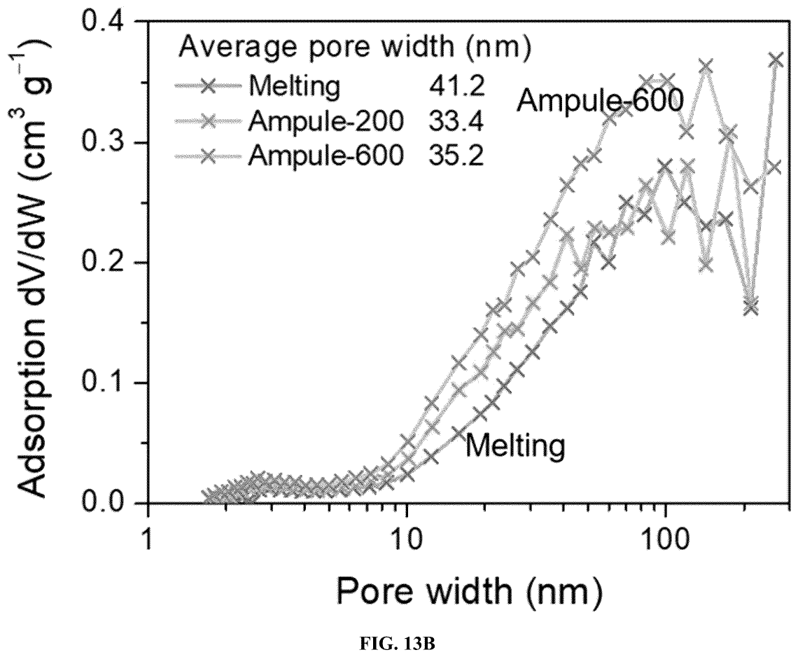

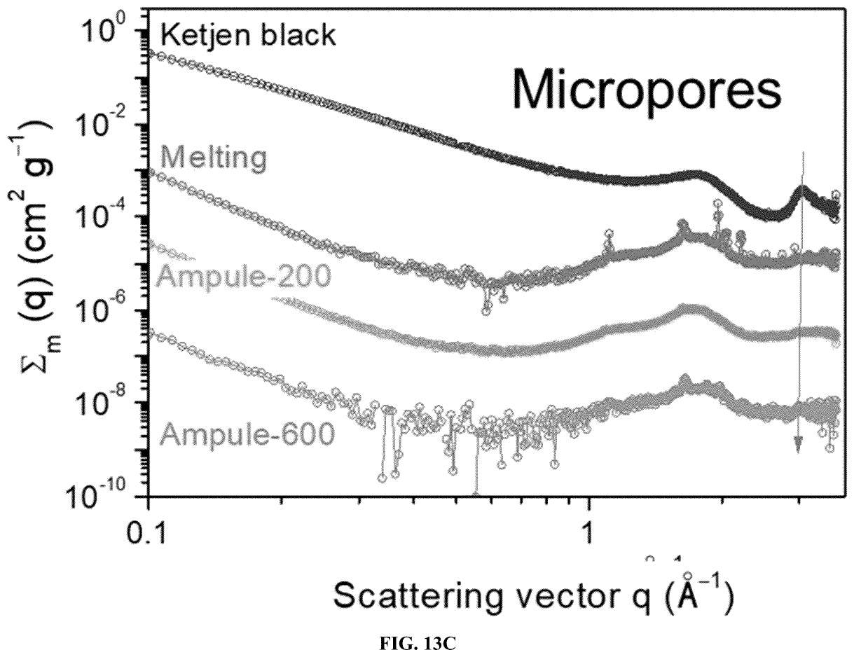

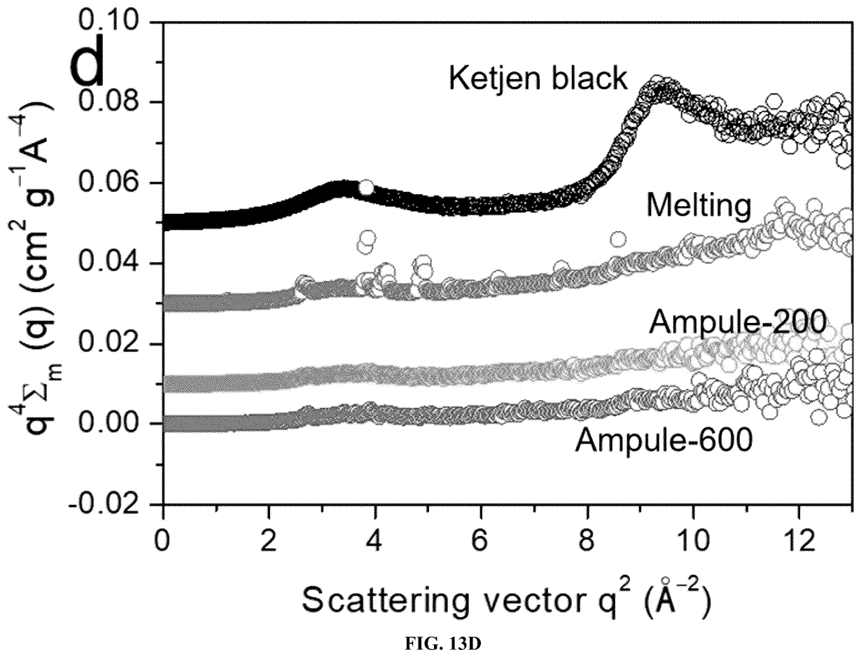

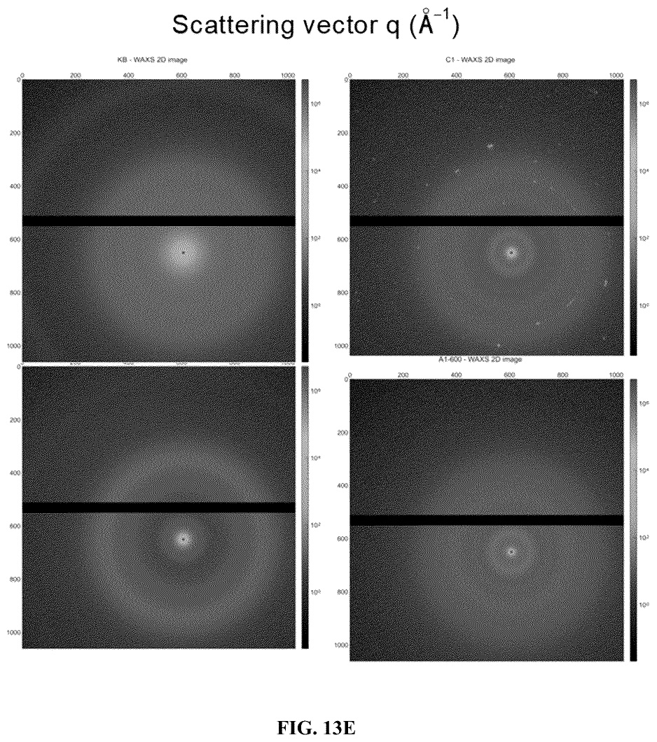

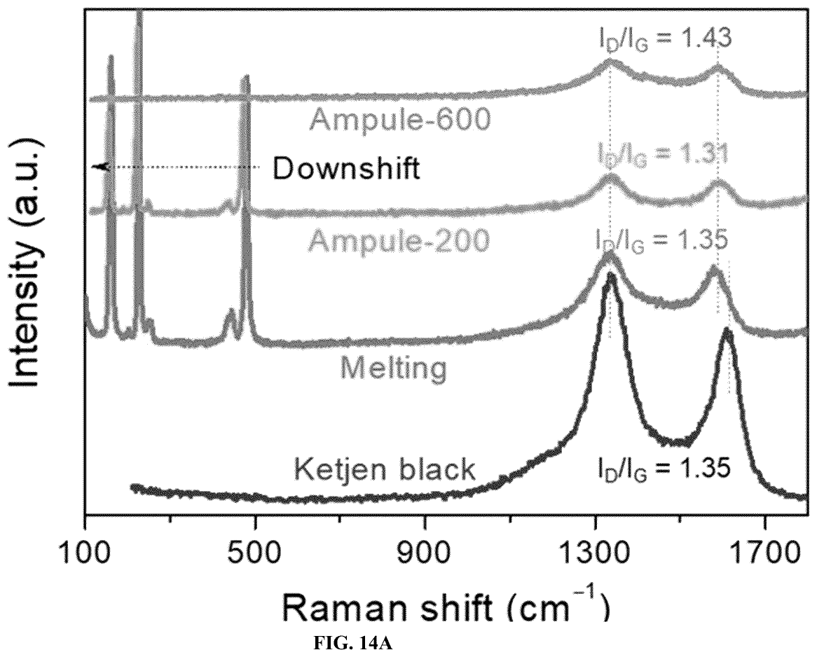

The structural origin of phase disordering in S/C composites was investigated by employing a comprehensive multiscale analysis that integrated BET surface area analysis using nitrogen adsorption and SAXS and WAXS techniques. FIGS. 13A and 13B display the nitrogen adsorption-desorption isotherms and pore size distributions from BJH method for pristine melt-diffused and sulfur-infiltrated S/C composites. Notably, the 600° C. S/C composite retained higher accessible porosity than the melt-diffused and 200° C. samples (21.1 m² g⁻¹ for melt-diffused; 30.6 m² g⁻¹ for Ampule-200; 46.5 m² g⁻¹ for Ampule-600), suggesting more efficient pore penetration and reduced surface-blocking sulfur aggregates. While BET analysis captures bulk textural changes, it cannot directly probe internal sulfur dispersion. To evaluate nanoscale morphology, SAXS measurements (FIGS. 13C and 13D) were performed. The Ampule-600 composite displayed a broad, featureless scattering profile with a smooth Porod slope, indicative of homogeneous sulfur distribution and reduced phase boundary contrast. In contrast, the melt-diffused and Ampule-200 samples showed steeper decays and distinct oscillations, reflecting heterogeneous sulfur loading and partial aggregation. The flatter q⁴I vs q² slope observed for Ampule-600 further supports the formation of a uniform, low-contrast S—C interface, characteristic of a non-crystalline confined phase. WAXS analysis (FIG. 13E) corroborated these findings. Pristine Ketjenblack exhibited diffuse scattering typical of amorphous carbon. The melt-diffused S/C sample showed discrete bright spots rather than continuous rings, signifying localized α-S crystallites on the carbon surface. The Ampule-200 sample exhibited faint continuous rings, indicative of moderate ordering, while the Ampule-600 sample showed a nearly featureless diffuse pattern, confirming a predominantly amorphous sulfur phase. Collectively, the SAXS and WAXS analyses demonstrate that high-temperature vapor-phase ampule synthesis (600° C.) yields homogeneously dispersed, non-crystalline sulfur confined within the carbon nanopores, effectively suppressing long-range ordering and recrystallization. This phase stabilization by vapor-assisted infiltration under high vacuum provides the structural foundation for improved electrochemical reversibility in Li/S cells.

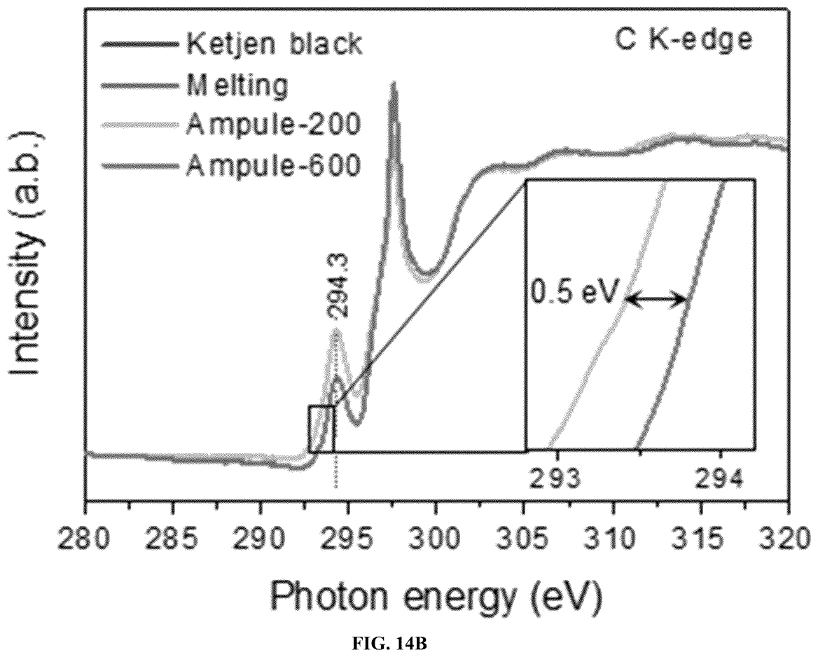

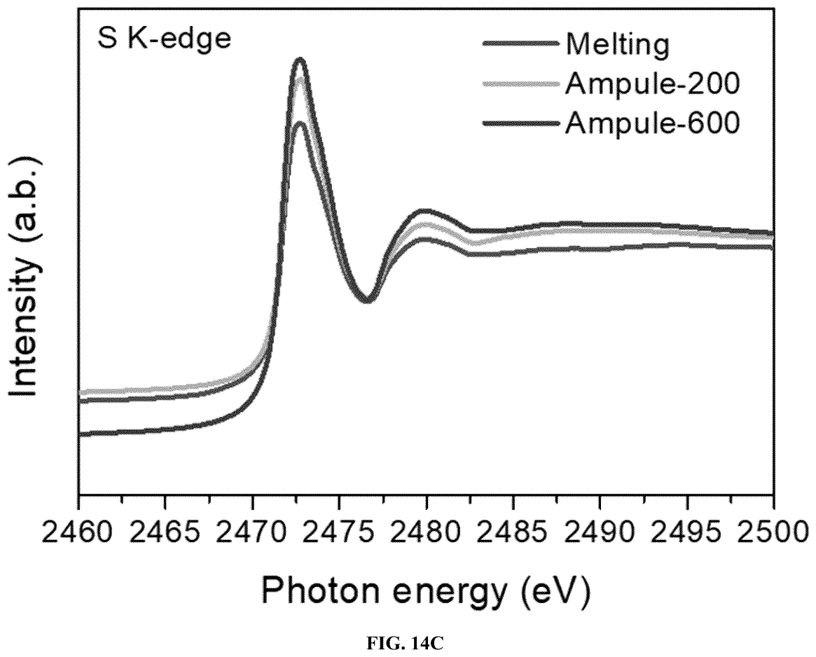

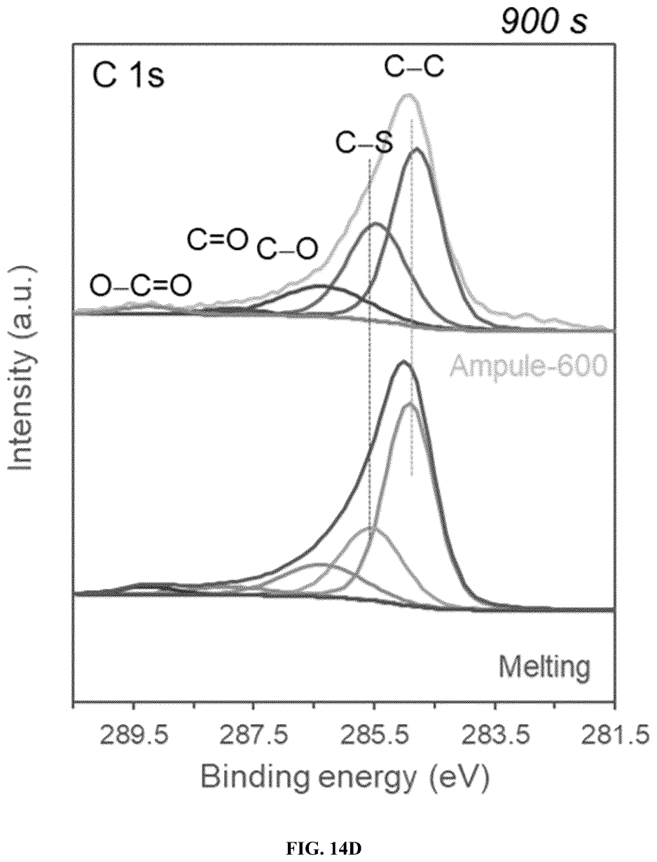

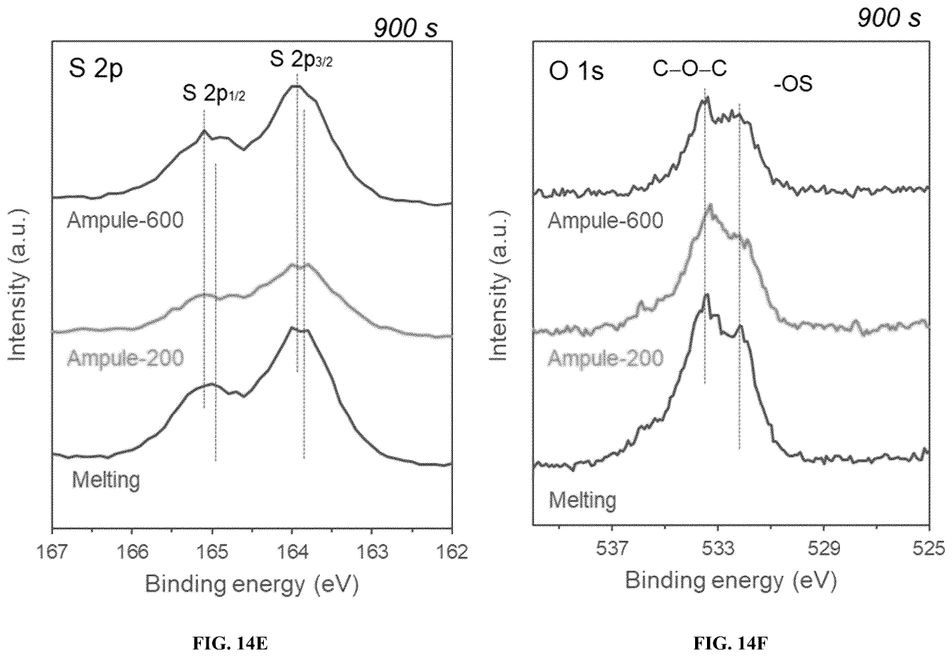

To elucidate the chemical and electronic characteristics of the confined amorphous sulfur, a series of vibrational and spectroscopic analyses were performed. FIG. 14A presents the Raman spectra of the S/C composites synthesized under different conditions. The melt-diffused sample exhibits pronounced vibrational bands corresponding to crystalline α-S, notably the A₁ and E modes near 150 and 220 cm⁻¹, confirming the dominance of long-range order. The 200° C. S/C composite shows markedly weaker α-S features, indicative of partial crystallinity suppression. In sharp contrast, the 600° C. S/C composite displays only the D and G bands of the carbon host without any sulfur-related peaks, signifying that sulfur exists in a molecularly dispersed or fully amorphous state. This absence of sulfur vibrational modes corroborates the WAXS and XRD results and confirms loss of long-range order within the confined phase. FIG. 6 presents TGA and differential scanning calorimetry (DSC) profiles, confirming that sulfur content across the three samples is approximately 70 wt. %. This uniformity in sulfur loading eliminates compositional disparity as a potential variable in explaining observed differences in structure and performance. Importantly, the thermal degradation profile of the 600° C. sample indicates a slightly broadened and delayed mass loss, possibly reflecting stronger confinement of sulfur or altered bonding characteristics. While the melt and 200° C. S/C exhibit well-defined endothermic peaks near 115-120° C., corresponding to the melting transition of crystalline sulfur, the 600° C. sample shows a broadened and less intense signal. This observation supports the hypothesis that sulfur exists in a disordered, kinetically trapped phase within the nanopores.

The C K-edge and S K-edge X-ray absorption spectra (FIGS. 14B and 14D) further reveal the evolution of local bonding and electronic configuration. The melt-diffused and 200° C. samples exhibit sharp resonance features characteristic of crystalline sulfur and intact C—C networks. In contrast, the 600° C. sample shows a smoother absorption onset and a slight blue-shift in the edge energy, suggesting modification of the electronic structure and formation of a disordered or polymeric sulfur phase. These changes imply stronger electronic coupling between sulfur and the carbon framework, consistent with confined non-crystalline sulfur stabilized within nanopores. Complementary XPS analysis (FIGS. 14D-14F) provides further evidence of altered chemical states. In the melt-diffused and 200° C. samples, the S 2p spectra exhibit well-defined doublets at 163.5-164.5 eV typical of elemental crystalline sulfur. Conversely, the 600° C. composite shows a discernible shift toward higher binding energies and a broadened peak envelope, indicative of multiple sulfur species and enhanced S—C interfacial interactions. The C 1s and O 1s spectra likewise display subtle upshifts and shoulder features corresponding to C—S and —SOₓ bonding environments. Taken together, the Raman, XAS, and XPS analyses collectively demonstrate that sulfur infiltrated under high-temperature, vapor-phase ampule conditions (600° C.) exists predominantly in a non-crystalline, electronically coupled, and chemically stabilized state within the carbon host. This integrative evidence establishes a clear spectroscopic signature of amorphous sulfur confinement and provides mechanistic insight into how vapor-phase infiltration under vacuum enables structural disorder and enhanced interfacial bonding crucial for Li/S cathode stability.

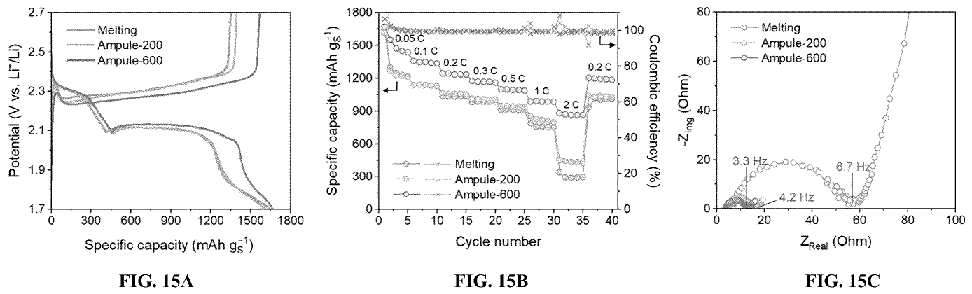

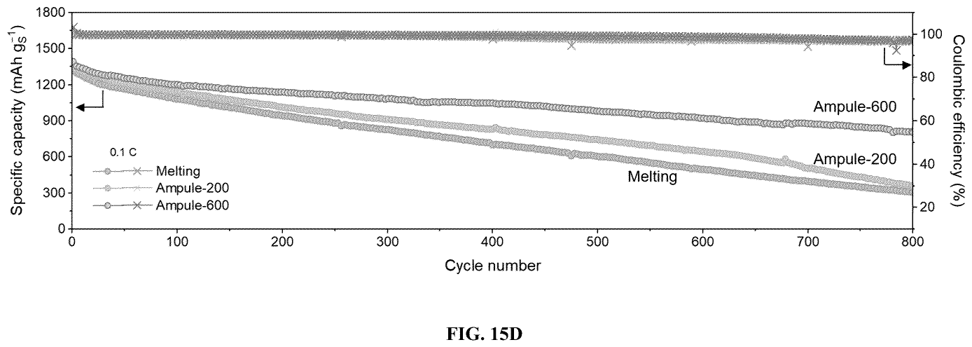

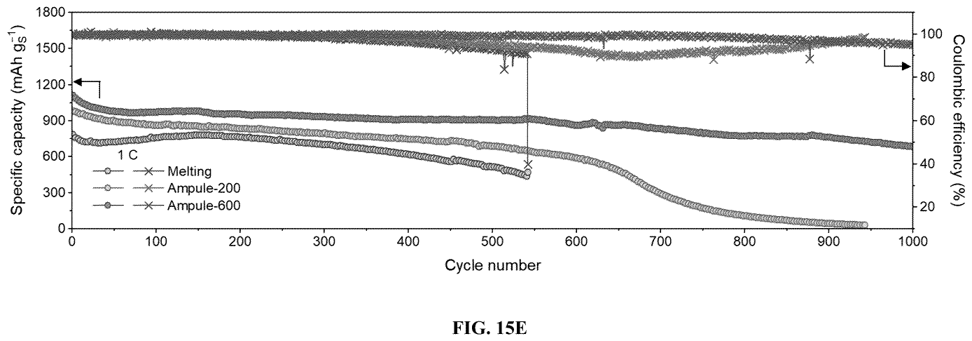

Electrochemical characterization was conducted to elucidate how sulfur phase state and spatial distribution influence redox kinetics and long-term stability. The initial discharge-charge profiles (FIG. 15A) exhibit two characteristic voltage plateaus near 2.3 V and 2.1 V (vs. Li⁺/Li), corresponding respectively to the stepwise reduction of elemental sulfur to higher-order polysulfides (Li₂Sₓ, 4≤x≤8) and their subsequent conversion to Li₂S. Notably, the Ampule-600 electrode delivered a high initial discharge capacity of 1646 mAh gₛ⁻¹ (98.4% of the theoretical value), outperforming the Ampule-200 (1612 mAh gₛ⁻¹) and melt-diffused (1669 mAh gₛ⁻¹) counterparts. The relatively higher capacity contribution from the upper plateau (˜2.3 V) in Ampule-600 suggests more complete sulfur conversion and improved electrolyte accessibility enabled by homogeneous sulfur dispersion. The rate performance (FIG. 15B) further highlights this advantage. Across current densities from C/20 to 2 C, all electrodes exhibited the expected capacity decay with increasing rate; however, Ampule-600 maintained 863 mAh gₛ⁻¹ at 2 C, corresponding to 51.7% retention relative to C/20, whereas the Ampule-200 and melt-diffused samples suffered from sharper declines due to sluggish charge-transfer kinetics and uneven sulfur utilization.

Electrochemical impedance spectroscopy (FIG. 15C) provided additional insight into interfacial processes. All cells displayed comparable ohmic resistances (3.7, 4.3, and 6.7 (2 for Ampule-600, Ampule-200, and melted, respectively), confirming identical cell configurations. Yet the charge-transfer resistance (R_{ct}) of Ampule-600 was markedly lower (8.7Ω) than that of Ampule-200 (10.7Ω) and melt-diffused (48.1Ω) electrodes, indicating faster ion/electron transport through the well-integrated sulfur-carbon interface. The weak Warburg region observed in the Ampule samples further implies reduced ion-diffusion limitations, consistent with efficient redox kinetics within the confined sulfur domains. Long-term cycling tests underscore the structural and electrochemical stability of the vapor-infiltrated composite. At 0.1 C (FIG. 15D), the Ampule-600 electrode sustained 806 mAh gₛ⁻¹ after 800 cycles, corresponding to 58% capacity retention and >97% Coulombic efficiency. Both the melt-diffused and Ampule-200 electrodes exhibited faster capacity decay and unstable efficiency, primarily due to incomplete confinement and persistent polysulfide dissolution. Even under high-rate conditions (1 C, FIG. 15E), Ampule-600 maintained 681 mAh gₛ⁻¹ after 1000 cycles, demonstrating exceptional redox reversibility and structural robustness.

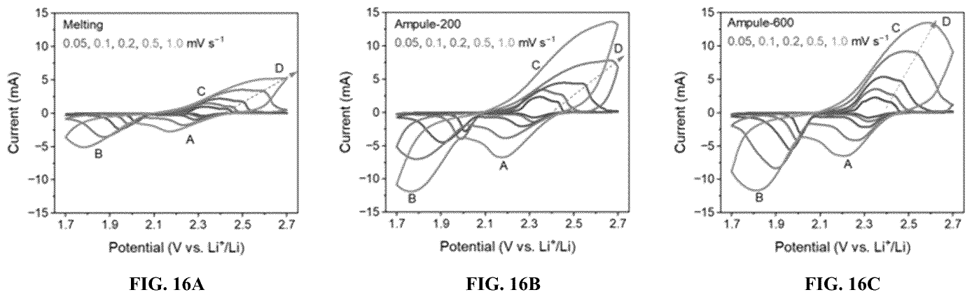

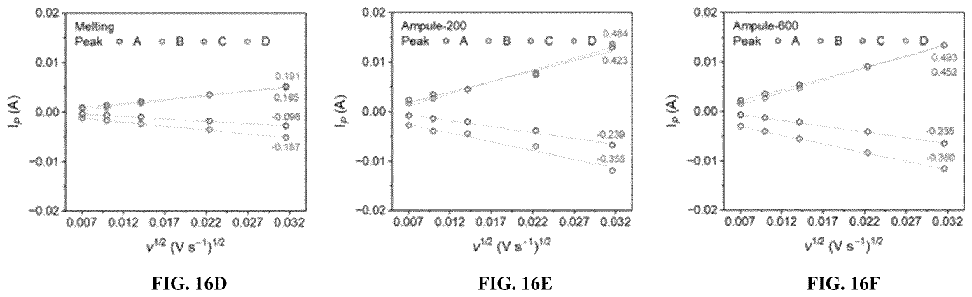

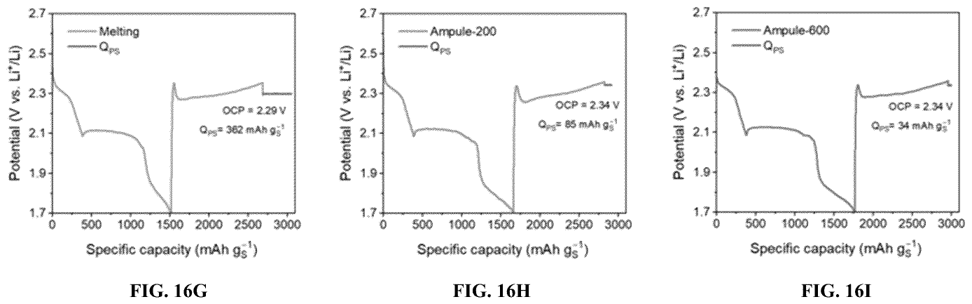

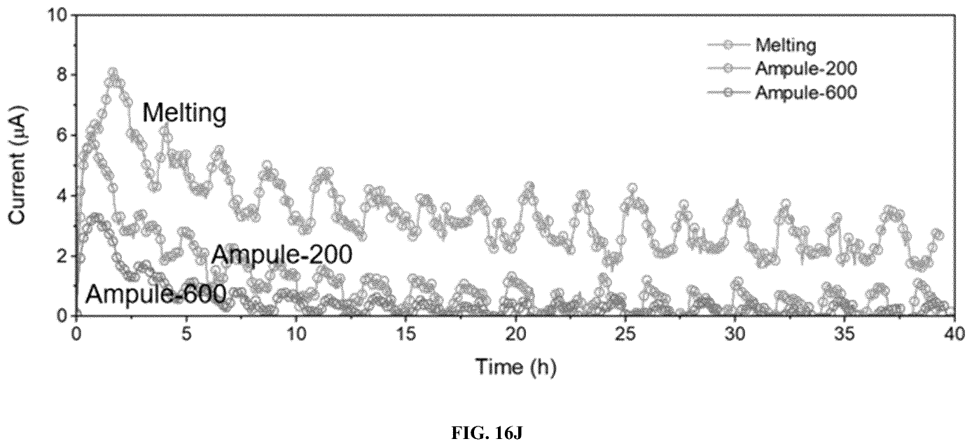

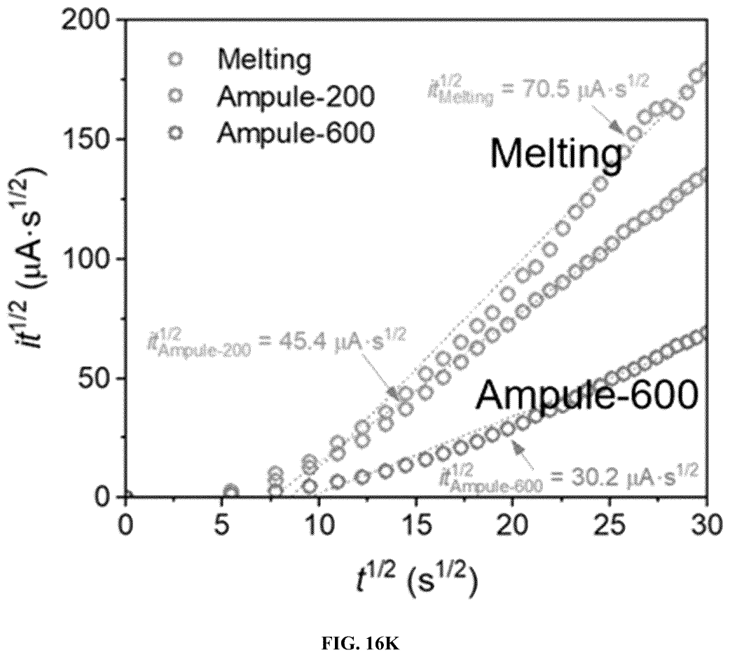

To elucidate ion transport behavior and redox kinetics in the sulfur-carbon electrodes, CV was performed at scan rates from 0.05 to 1.0 mV s⁻¹ (FIGS. 16A-16C). All samples exhibited four well-defined redox peaks (A-D), corresponding to the stepwise reduction and oxidation of sulfur species. Among them, the Ampule-600 electrode displayed the least peak shift and narrowing with increasing scan rate, signifying high kinetic reversibility and low polarization during cycling. In contrast, the melt-diffused electrode showed broad, merged peaks with pronounced potential shifts, suggesting sluggish redox transitions and unstable intermediates due to heterogeneous sulfur distribution and weak interfacial contact with the electrolyte. The Li⁺ diffusion behavior of each electrode was further assessed using the Randles-Sevcik equation:

$${i}_{P} = 2.69 \times 1 {0}^{5} \times {n}^{3 / 2} {AD}_{Li}^{1 / 2} {C}_{L i} {v}^{1 / 2} \qquad ( 1 )$$

where i_{P} is the peak current, n is the number of electrons transferred, A is the electrode area, C_{Li} is the Li⁺ concentration, and v is the scan rate. As expected, the peak current scaled linearly with v^{1/2}, confirming diffusion-controlled processes (FIGS. 16D-16F). From the fitted slopes, the Ampule-600 sample exhibited the highest apparent D_{Li} across both cathodic and anodic processes, followed by Ampule-200 and then the melt-diffused composite. The extracted diffusion coefficients (Table 1 below) span from 5.9×10⁻⁷ to 2.6×10⁻⁶ cm² s⁻¹ for Ampule-600, an order of magnitude higher than those of the melt-diffused electrode, highlighting that vapor-phase infiltration at elevated temperature enhances ionic transport by improving pore connectivity and sulfur homogeneity. It should be noted that the diffusion coefficients were calculated assuming the geometric electrode area as the active surface, which may lead to an overestimation in absolute terms. However, since all samples were fabricated and tested under identical conditions, including electrolyte composition, sulfur loading, and cell geometry, the relative trend remains valid and meaningful. This analysis reinforces that the Ampule-600 sample offers the most favorable kinetic pathway for Li+ transport among the three, which is consistent with the improved charge-transfer resistance and electrochemical performance observed in other measurements.

Table 1. Calculated Li⁺ diffusion coefficients D_{Li} for cathodic and anodic peaks based on Randles-Sevcik analysis of CV curves (FIGS. 16D-16F). The slope values were extracted from linear fits of i_{P} vs. v^{1/2}.

TABLE 1

| Electrodes | Melting | Ampule-200 | Almpue-600 |
|---|---|---|---|
| D_{Li} of peak A (cm² s⁻¹) | 9.97 × 10⁻⁸ | 6.18 × 10⁻⁷ | 5.97 × 10⁻⁷ |
| D_{Li} of peak B (cm² s⁻¹) | 2.67 × 10⁻⁷ | 1.36 × 10⁻⁶ | 1.36 × 10⁻⁶ |
| D_{Li} of peak C (cm² s⁻¹) | 2.94 × 10⁻⁷ | 1.94 × 10⁻⁶ | 2.21 × 10⁻⁶ |
| D_{Li} of peak D (cm² s⁻¹) | 3.95 × 10⁻⁷ | 2.53 × 10⁻⁶ | 2.63 × 10⁻⁶ |

Beyond ion diffusion, shuttle suppression was evaluated by open-circuit potential (OCP) relaxation and chronoamperometric measurements (FIGS. 16G-16K). When held near the equilibrium potential of polysulfide-rich regions (≈2.34 V), the melt-diffused cell exhibited large, persistent oscillating currents (>3.4 μA for 40 h), indicative of continuous polysulfide reduction at the lithium anode. This corresponded to a shuttle-induced capacity loss of 362 mAh gₛ⁻¹ (≈31% of the initial discharge). By contrast, the Ampule-600 cell maintained a nearly stable baseline current (<0.46 μA) with minimal loss (34 mAh gₛ⁻¹, ≈2.9%), while Ampule-200 showed intermediate suppression (0.98 μA, ≈7.3%). To provide a more quantitative understanding, the experimental diffusion coefficient of Li—PS (D_{Shuttle}) was estimated based on the intercept of the it^{1/2} vs. t^{1/2} linear fit derived from the Cottrell equation:

$$i ( t ) = n F {A ( D / π t )}^{1 / 2} {C}_{0} \qquad ( 2 )$$

Here, i(t) is the transient current, n is the number of electrons transferred (assumed to be 1), F is Faraday's constant, A is the electrode area, C is the bulk concentration of Li⁺, and D is the diffusion coefficient. By rearranging the equation (2), one obtains below:

$$i ( t ) \cdot {t}^{1 / 2} = n F {A ( D / π )}^{1 / 2} {C}_{0} = a \qquad ( 3 )$$

a is the intercept of linear fit curve of it^{1/2} vs. t^{1/2} plot (when t^{1/2} is 0). Thus, the a can be used to estimate D, as it is inversely proportional to D^{1/2}. Although absolute quantification is limited due to uncertainty in exact A, a comparison of inverse square intercept values offers a valid assessment of relative diffusion kinetics across samples. Assuming equal electrode area and similar bulk Li—PS concentration (C₀), the relative D_{Shuttle} values were compared based on the intercepts in FIG. 16K. To ensure the validity of the semi-infinite linear diffusion model, linear fitting was performed only within the initial 1000 s region of the it^{1/2} vs. t^{1/2} plot. This time window was selected based on the characteristic Cottrell behavior, where the diffusion of Li—PS can be approximated as planar and semi-infinite. Beyond this region, deviations from linearity were observed due to shuttle current accumulation and potential redistribution effects, which can obscure the accurate extraction of the diffusion-limited current. Ampule-600 displayed the smallest intercept (30.2 μA s^{-1/2}), corresponding to the lowest effective D_{Shuttle} (3.08×10⁻¹³/A² cm² s⁻¹), while the Melting (70 μA s^{-1/2}) and Ampule-200 (45.4 μA s^{-1/2}) had the higher values (1.68×10^{-1/2}/A² and 6.96×10⁻¹³/A² cm² s⁻¹, respectively). While the difference in the calculated Li—PS D_{Shuttle} only reaches one order of magnitude, the ˜10-fold reduction observed in the Ampule-600 still suggests a significant suppression of Li—PS shuttle phenomena. The reduced diffusivity is attributed to the compact, passivating surface layer induced by the ampule infiltration process, which hinders the outward migration of soluble intermediates. Overall, the CV and shuttle current analyses consistently indicate that thermally infiltrated sulfur electrodes, particularly Ampule-600, achieve enhanced redox kinetics and superior suppression of parasitic side reactions. These kinetic advantages are expected to contribute to prolonged cycling stability.

The sealed container method and system as disclosed herein is useful to incorporate sulfur into a carbon host material to form the disclosed S/C composite. Forming S/C bonds on the surface of the desorbed carbon helps to immobilize the sulfur within the carbon matrix, preventing its migration or loss during cycling and reducing the effects of the inherent low conductivity of sulfur. Further, sulfur dispersed at a nano-scale according to the disclosed system and method ameliorates the known volumetric expansion of sulfur during lithiation.

The disclosed method can be both scalable and consistently reproducible at a high-volume manufacturing scale. The container-based method and closed reactor system utilizing the sealed container offers precise control over the infiltration and crystallinity of sulfur in the carbon matrix, making it suitable for commercial-scale production of Li/S batteries. The ability to prevent sulfur agglomeration and ensure uniform sulfur distribution according to the disclosed method and system improves the stability and performance of sulfur-carbon composites, enhancing the practical applicability of Li/S batteries in commercial energy storage systems.

This disclosure, its aspects and embodiments, are not limited to the specific material types, components, methods, or other examples disclosed herein. Many additional material types, components, methods, and procedures known in the art are contemplated for use with particular implementations from this disclosure. Accordingly, for example, although particular implementations are disclosed, such implementations and implementing components may comprise any components, models, types, materials, versions, quantities, and/or the like as is known in the art for such systems and implementing components, consistent with the intended operation.

In places where the description above refers to particular implementations, it should be readily apparent that a number of modifications may be made without departing from the spirit thereof and that these implementations may be applied to other implementations disclosed or undisclosed. The presently disclosed inventions and embodiments are, therefore, to be considered in all respects as illustrative and not restrictive.

What is claimed is:

1. A method of making a sulfur-carbon composite, the method comprising:
providing an amorphous carbon powder comprising nanometer-sized pores disposed in a container;
gaseously coupling a staging tube containing a sulfur source to the amorphous carbon powder;
evacuating the container and the staging tube to remove ambient air and surface-adsorbed gaseous species;
backfilling the container to about ⅔ atmosphere absolute (ATA) with a high purity inert gas;
desorbing the amorphous carbon powder by:
heating the container proximal to the amorphous carbon powder;
evacuating the container to about ⅓ ATA to at least partially remove gaseous species and moisture;
backfilling the container to about ⅔ ATA with the high purity inert gas; and
repeating heating, evacuating, and backfilling until a predetermined desorption temperature is reached;
cooling the container to room temperature under the high purity inert gas;
transferring the sulfur source from the staging tube onto the desorbed amorphous carbon powder in the container;
evacuating the container to a vacuum and sealing the desorbed amorphous carbon powder and the sulfur source in the container;
applying a temperature gradient across the container, with a high temperature zone adjacent the desorbed amorphous carbon powder and the sulfur source at a sulfur infiltration temperature, and a low temperature zone distal to the desorbed amorphous carbon powder and the sulfur source;
maintaining the temperature gradient for a duration sufficient to vaporize and infiltrate sulfur into the desorbed amorphous carbon powder to form a composite; and
cooling the container to condense excess sulfur away from the composite.

2. The method of claim 1, further comprising maintaining the temperature gradient during cooling, wherein the temperature gradient causes the excess sulfur to condense in the low temperature zone distal to the composite.

3. The method of making a sulfur-carbon composite of claim 1, wherein the desorption temperature is substantially equal to or greater than the sulfur infiltration temperature.

4. The method of claim 1, wherein the sulfur infiltration temperature is within a range of from about 400° C. to about 800° C.

5. The method of claim 1, wherein the container is filled with the amorphous carbon powder to between about 30% and 60% of its volume.

6. The method of claim 1, wherein the vacuum is about 9×10⁻⁵ torr.

7. The method of claim 1, further comprising hermetically sealing the container.

8. The method of claim 1, wherein transferring the sulfur source from the staging tube onto the desorbed amorphous carbon powder is performed under high purity inert gas.

9. A system for nano-scale dispersion of sulfur into a porous carbon electrode, comprising:
a container having carbon powder disposed therein, the carbon powder comprising nanometer-sized pores;
a staging tube having sulfur disposed therein, the staging tube coupled to the container with an O-ring union tee vacuum fitting, the staging tube configured to transfer the sulfur onto the carbon powder disposed in the container;
a vacuum pump coupled to the container and the staging tube via the O-ring union tee vacuum fitting;
a gas supply coupled to the container and the staging tube via the O-ring union tee vacuum fitting; and
a heating source configured to receive the container, wherein the staging tube is disposed away from the heating source when the container is disposed in the heating source.

10. The system of claim 9, wherein the container is configured for sealing below the O-ring union tee vacuum fitting.

11. The system of claim 10, wherein the container is configured for sealing under high vacuum.

12. The system of claim 10, wherein the container is configured for hermetic sealing.

13. The system of claim 9, wherein the heating source is configured to apply a temperature gradient across the container to facilitate sulfur infiltration and condensation control.

14. A sulfur-carbon composite, comprising:
porous carbon substantially free of moisture and adsorbed gaseous species and having nanometer-scale pores disposed therein; and
nanometer-scale sulfur dispersed in the nanometer-scale pores and on a surface of the porous carbon, wherein the sulfur has a nanometer-scale particle size.

15. The sulfur-carbon composite of claim 14, wherein the sulfur comprises non-crystalline and/or nanocrystalline sulfur.

16. The sulfur-carbon composite of claim 14, wherein the sulfur is immobilized within the nanometer-scale pores of the sulfur-carbon composite.

17. The sulfur-carbon composite of claim 14, wherein the porous carbon comprises an interconnected, electrically conductive network.

18. The sulfur-carbon composite of claim 14, wherein the sulfur-carbon composite is free of sulfur agglomerates and aggregates.

19. The sulfur-carbon composite of claim 14, wherein the sulfur is chemically bonded with the porous carbon.

20. The sulfur-carbon composite of claim 14, wherein the sulfur is distributed uniformly within the porous carbon.
